(19) United States
(12) Patent Application Publication
(10) Pub. No.: US 2013/0342255 A1
(43) Pub. Date: Dec. 26, 2013

(54) SIGNAL DELAY DEVICE AND CONTROL METHOD

(71) Applicant: FUJITSU LIMITED, Kawasaki (JP)

(72) Inventor: Yoshihiko SATSUKAWA, Kawasaki (JP)

(73) Assignee: FUJITSU LIMITED, Kawasaki (JP)

(21) Appl. No.: 14/014,725

(22) Filed: Aug. 30, 2013

Related U.S. Application Data
(63) Continuation of application No. PCT/JP2011/054655, filed on Mar. 1, 2011.

(51) Int. Cl. H03K 5/14

(52) U.S. Cl. CPC H03K 5/14
USPC 327/276

(57) ABSTRACT

A signal delay device includes a delay unit including delay parts connected to one another in series and generating a delay signal; a selection unit to output the delay signal and including selectors connected to one another in series and outputting the delay signal, each selector receiving an output of one of the delay parts, being supplied with an output of former selector, and outputting the output of the delay part or the output of the former selector, based on a selection signal; a register unit holding delay setting data to set an amount of delay of the signal delay device; and a selection signal generator generating a selection signal indicating one of the selectors selecting an output of one of the delay parts based on the delay setting data and outputting the generated selection signal to the selection unit.

### CROSS-REFERENCE TO RELATED APPLICATIONS

The present application is a U.S. continuation application filed under 35 USC 111(a) claiming benefit of priority under 35 U.S.C. 120 and 365(c) of PCT International Application No. PCT/JP2011/054655 filed on Mar. 1, 2011, the entire contents of which are incorporated herein by reference.

### FIELD

The disclosures herein are related to a signal delay device and a control method of the signal delay device.

### BACKGROUND

There is known in the related art a signal delay device configured to assign a delay to an input signal such as a clock signal of a semiconductor circuit device such as a large scale integrated circuit (LSI).

An example of such a signal delay device inputs signals to a plurality of delay parts, sets any one of the delay parts in an operating mode based on a switching control signal, and outputs a signal to which a delay is assigned by the delay part set in the operating mode.

The related art signal delay device needs to carry out processing such as computing an amount of delay or assigning weights to the amount of delay so as to set the amount of delay assigned to an input signal.

This indicates that it may be complicated to set the amount of delay.

### RELATED ART DOCUMENTS

### Patent Document

Patent Document 1: Japanese Laid-open Patent Publication No. 11-68528

### SUMMARY

According to one aspect of the present invention, there is provided a signal delay device outputting a delay signal obtained by assigning a delay to an input signal. The signal delay device includes a delay unit including a plurality of delay parts connected to one another in series and configured to generate a delay signal, the delay signal being obtained by causing at least one of the delay parts to assign a delay to an input signal; a selection unit configured to output the delay signal, the selection unit including a plurality of selectors connected to one another in series, each of the selectors being configured to receive an output of a corresponding one of the delay parts, each of the selectors excluding a head one of the selectors being supplied with an output of a corresponding one of the former selectors, and outputting one of the output of the corresponding one of the delay parts and the output of the corresponding one of the former selectors, based on a selection signal supplied therein; a register unit configured to hold delay setting data to set an amount of delay of the signal delay device; and a selection signal generator configured to generate the selection signal indicating one of the selectors selecting an output of a corresponding one of the delay parts based on the delay setting data held by the register unit and output the generated selection signal to the selection unit.

The object and advantages of the invention will be realized and attained by means of the elements and combinations particularly pointed out in the appended claims.

It is to be understood that both the foregoing general description and the following detailed description are exemplary and explanatory and are not restrictive of the invention as claimed.

Other objects, features, and advantages of the present invention will become more apparent from the following detailed description when read in conjunction with the accompanying drawings.

### BRIEF DESCRIPTION OF DRAWINGS

FIG. 1A is a diagram illustrating a delay adjustment circuit 10 of a comparative example of a signal delay device;

FIG. 1B is a diagram illustrating a delay adjustment circuit 50 of a comparative example of a signal delay device;

FIG. 2 is a diagram illustrating the comparative examples of the delay adjustment circuits 10 and 50, and shift registers 40A and 40B;

FIG. 3 is a diagram illustrating a corresponding relationship between data held by the shift registers 40A and 40B connected to the comparative examples of the delay adjustment circuits 10 and 50;

FIG. 4A is a diagram illustrating a comparative example of a delay adjustment circuit 10A having a power-saving mechanism;

FIG. 4B is a diagram illustrating a signal path when a signal turning point is switched in the delay adjustment circuit 10A of FIG. 4A;

FIG. 5 is a timing chart illustrating operations when a data signal is captured;

FIG. 6 is a timing chart illustrating operations when a data signal is captured;

FIG. 7 is a timing chart illustrating operations when a data signal is captured;

FIG. 8 is a timing chart illustrating operations when a data signal is captured;

FIG. 9 is a diagram illustrating an information processing apparatus including a signal delay device 100 of a first embodiment;

FIG. 10 is a diagram illustrating the signal delay device 100 of the first embodiment;

FIG. 11 is a diagram illustrating a circuit configuration of a delay adjustment determining part 140 of the signal delay device 100 of the first embodiment;

FIG. 12 is a timing chart representing operations of the delay adjustment determining part 140 of the signal delay device 100 of the first embodiment;

FIG. 13 is a diagram illustrating a circuit configuration of a delay setting data generator 150 of the signal delay device 100 of the first embodiment;

FIG. 14A is a diagram illustrating a delay adjustment circuit 110A for fine adjustment, a selection signal generator 120, a shift register 130, and a change flag FF 170 of the signal delay device 100 of the first embodiment;

FIG. 14B is a diagram illustrating a circuit configuration example of a part of the selection signal generator 120;

FIG. 15A is a diagram illustrating an example of delay setting data held by the shift register 130 of the signal delay device 100 of the first embodiment;

FIG. 15B is a diagram illustrating delay setting data held by the shift register 130 of the signal delay device 100 of the first embodiment together with the change flag and a selection signal;

FIG. 16 is a flowchart illustrating a delay process in the signal delay device 100 of the first embodiment;

FIG. 17 is a diagram illustrating a timing chart indicating a relationship between the delay setting data and the selection signals in the delay adjustment circuit 110A for fine adjustment of the signal delay device 100 of the first embodiment;

FIG. 18 is a diagram illustrating a signal delay device 200 of a second embodiment;

FIG. 19 is a diagram illustrating circuit configurations of a fine delay adjustment circuit 110A, a selection signal generator 220, and a shift register 230 of the signal delay device 200 of the second embodiment;

FIG. 20 is a table illustrating combinations of the delay setting data for acquiring the selection signals 1 to 4, and output signals of a NAND circuit 251 to be output as the selection signals 1 to 4;

FIG. 21 is a schematic diagram illustrating switching of a signal turning point of the fine delay adjustment circuit 110A of the signal delay device 200 of the second embodiment; and

FIG. 22 is a diagram illustrating a timing chart indicating a relationship between the delay setting data and the selection signals in the delay adjustment circuit 110A for fine adjustment of the signal delay device 200 of the first embodiment.

### DESCRIPTION OF EMBODIMENTS

It may be desirable to provide a signal delay device and a control method of the signal delay device capable of simply setting an amount of delay to be assigned to an input signal.

Preferred embodiments will be described with reference to the accompanying drawings. Specifically, a description is given of embodiments to which a signal delay device and a control method of the signal delay device are applied.

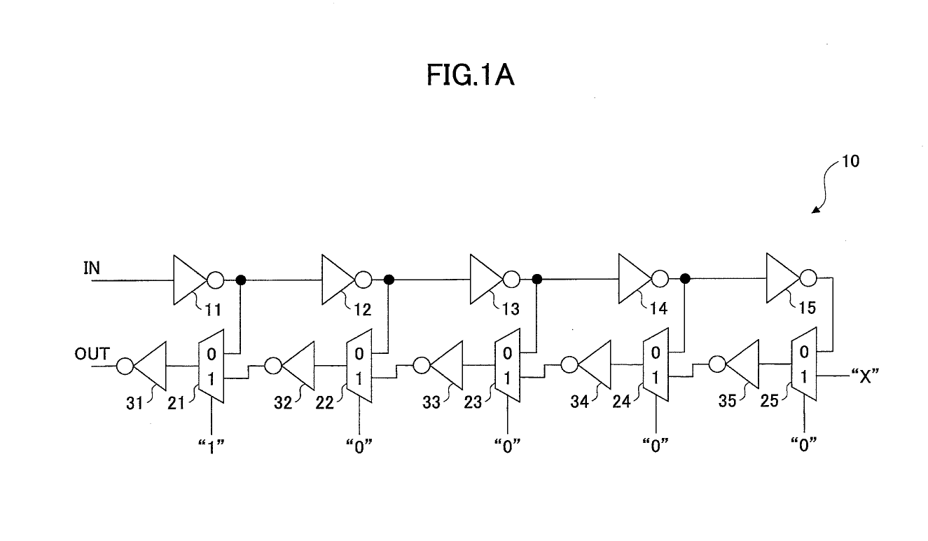

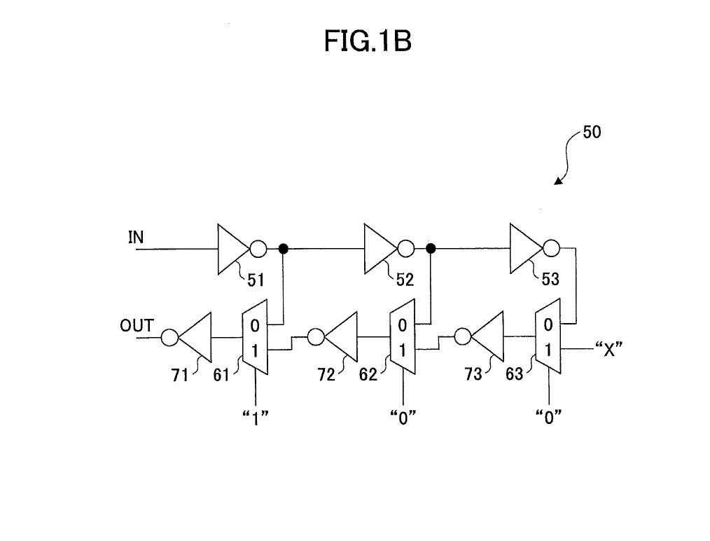

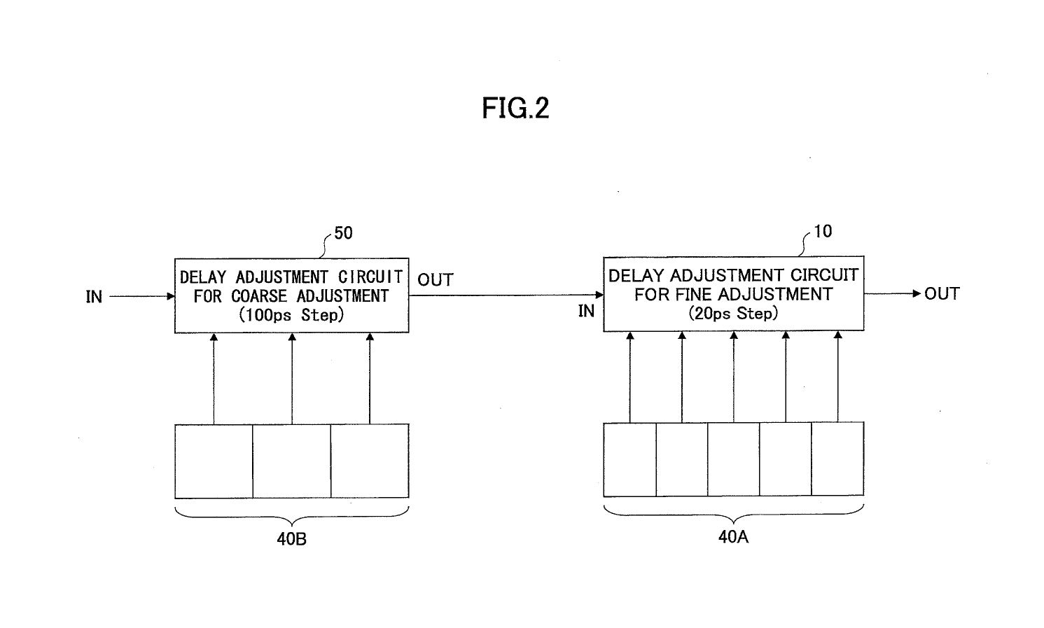

First, a comparative example of a signal delay device will be described with reference to FIGS. 1A to 2 prior to illustration of a signal delay device of first and second embodiments.

FIGS. 1A and 1B are diagrams respectively illustrating delay adjustment circuits of the comparative example of the signal delay device.

The delay adjustment circuit 10 of the comparative example of the signal delay device illustrated in FIG. 1A includes inverters 11, 12, 13, 14 and 15, selectors 21, 22, 23, 24 and 25, and inverters 31, 32, 33, 34 and 35.

The inverters 11 to 15, selectors 21 to 25, and inverters 31 to 35 serve as delay elements.

Further, the inverters 11 to 15 serve as forwarding-side inverters configured to propagate signals to selectors 21 to 25 respectively serving as signal turning points. The inverters 31 to 35 serve as returning-side inverters configured to receive the signals returned from the respective selectors 21 to 25.

The inverters 11 to 15 serve as NOT circuits configured to invert input signals to output inverted signals.

The inverters 11 to 15 are connected in series by having output terminals connected to corresponding sequential input terminals. The input terminal of the inverter 11 is connected to an input terminal IN of the delay adjustment circuit 10, and the output terminal of the inverter 15 is connected to a first input terminal of the selector 25.

The selectors 21 to 25 are disposed corresponding to the inverters 11 to 15. Each of the selectors 21 to 25 includes two input terminals (first and second input terminals) configured to select any one of the input signals based on levels (“1” or “0”) of the input signals, and output the selected signal.

The inverters 31 to 35 serve as NOT circuits configured to invert input signals to output inverted signals, and are disposed corresponding to the selectors 21 to 25. The inverters 31 to 35 are alternately connected to the selectors 21 to 25 in series, and configured to invert output signals of the respective selectors 21 to 25 and output the inverted signals.

The output terminal of the inverter 15 is connected to a first input terminal of the selector 25. Data X are input into a second input terminal of the selector 25. Note that the data X are fixed data of one of “0” and “1”.

The output terminal of the inverter 14 is connected to a first input terminal of the selector 24, and the output terminal of the inverter 35 is connected to a second input terminal of the selector 24.

The output terminal of the inverter 13 is connected to a first input terminal of the selector 23, and the output terminal of the inverter 34 is connected to a second input terminal of the selector 23.

The output terminal of the inverter 12 is connected to a first input terminal of the selector 22, and the output terminal of the inverter 33 is connected to a second input terminal of the selector 22.

The output terminal of the inverter 11 is connected to a first input terminal of the selector 21, and the output terminal of the inverter 32 is connected to a second input terminal of the selector 21.

The output terminal of the selector 21 is connected to the input terminal of the inverter 31, and the output terminal of the inverter 31 is connected to the output terminal OUT of the delay adjustment circuit 10.

The delay adjustment circuit 10 selects one of the selectors 21 to 25 from which the signal input into the input terminal IN is to be returned, so as to adjust a delay time of the signal input into the input terminal IN and output the adjusted signal from the output terminal OUT.

That is, the delay adjustment circuit 10 adjusts the amount of delay by selecting the number of inverters through which the input signal input into the input terminal IN passes using the selectors 21 to 25.

A signal turning point of the signal supplied from the input terminal IN is determined based on any one of the selectors 21 to 25 that initially sets the selection signal at a “0” level as viewed from the input terminal IN.

Further, the number of inverters through which the input signal supplied from the input terminal IN passes is an even number of inverters. Hence, the polarity of the signal input from the input terminal IN is identical to the polarity of the signal output from the output terminal OUT.

In the delay adjustment circuit 10, when the selection signals input into the selectors 21 to 25 are set as “1”, “0”, “0”, “0” and “0”, respectively, the selector 22 selects the output signal of the inverter 12 as illustrated in FIG. 1A. Hence, the signal input into the input terminal IN is propagated from the inverter 11 to the inverter 12, input from the output terminal of the inverter 12 into the selector 22, and returned at the selector 22.

When the signal is returned at the selector 22, the inverters 13, 14, and 15, the selectors 23, 24 and 25, and the inverters 33, 34 and 35 are excluded from a propagation path of the signal input from the input terminal IN.

The delay adjustment circuit 50 of the comparative example of the signal delay device illustrated in FIG. 1B includes inverters 51, 52 and 53, selector 61, 62 and 63, and inverters 71, 72 and 73.

The inverters 51, 52 and 53, the selector 61, 62 and 63, and the inverters 71, 72 and 73 of the comparative example of the delay adjustment circuit 50 respectively include circuit configurations having the numbers of forwarding-side inverters, selectors, and returning-side inverters of the comparative example of the delay adjustment circuit 10 that are reduced from five to three.

The inverters 51, 52 and 53, the selectors 61, 62 and 63, and the inverters 71, 72 and 73 correspond to the inverters 11, 12 and 13, the selectors 21, 22 and 23, and the inverters 31, 32 and 33 of the comparative example of the delay adjustment circuit 10, and connecting relationships between the inverters 51, 52 and 53, the selectors 61, 62 and 63, and the inverters 71, 72 and 73 are similar to those between the inverters 11, 12 and 13, the selectors 21, 22 and 23, and the inverters 31, 32 and 33 of the comparative example of the delay adjustment circuit 10 except that data X are supplied to the second input terminal of the selector 63.

The delay adjustment circuit 50 of the comparative example of the signal delay device has settings of a span of an adjustable amount of a delay range wider than the span of the adjustable amount of the delay range of the comparative example of the delay adjustment circuit 10. Hence, the delay adjustment circuit 10 is used for fine adjustment whereas the delay adjustment circuit 50 of the signal delay device is used for coarse adjustment.

Next, a description will be given, with reference to FIG. 2, of shift registers configured to output a selection signal to be supplied to the comparative example of the delay adjustment circuit 10.

FIG. 2 is a diagram illustrating the delay adjustment circuits 10 and 50, and shift registers 40A and 40B.

The delay adjustment circuit 10 illustrated in FIG. 2 is provided for fine adjustment of a delay time. For example, the delay adjustment circuit 10 is configured to adjust the delay time every 20 pico second (ps). Further, the delay adjustment circuit 50 illustrated in FIG. 2 is provided for coarse adjustment of a delay time. For example, the delay adjustment circuit 50 is configured to adjust the delay time every 100 ps.

Since the delay adjustment circuit 10 includes five selectors 21 to 25, the delay adjustment circuit 10 receives a 5-bit selection signal from the 5-bit shift register 40A.

Since the delay adjustment circuit 50 includes three selectors 61 to 63, the delay adjustment circuit 50 receives a 3-bit selection signal from the 3-bit shift register 40B.

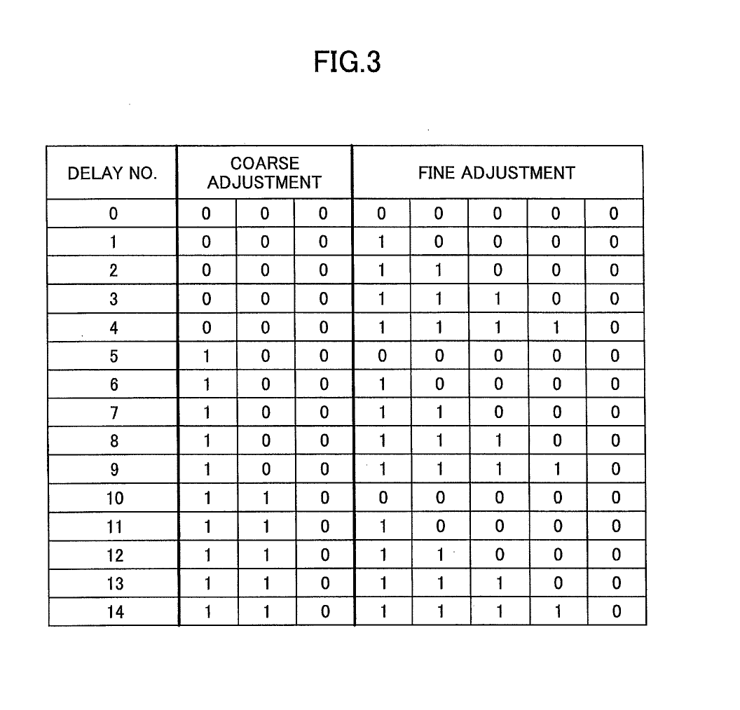

Next, a description will be given, with reference to FIG. 3, of data representing the selection signals that are held by the shift registers 40A and 40B.

FIG. 3 is a diagram illustrating a corresponding relationship between data held by the shift registers 40A and 40B connected to the comparative examples of the delay adjustment circuits 10 and 50 and delay numbers (delay Nos.) corresponding to the delay time of the delay adjustment circuit. In the comparative examples of the delay adjustment circuits 10 and 50, the selection signals are supplied from the shift registers 40A and 40B to the selectors 21 to 25 and 61 to 63 (see FIGS. 1A and 1B).

As illustrated in FIG. 3, the selection signal includes 5-bit data for fine adjustment and 3-bit data for coarse adjustment. The 5-bit data for fine adjustment and 3-bit data for coarse adjustment are output from the shift registers 40A and 40B as the selection signals, respectively. In FIG. 3, each of 0 to 14 delay numbers (delay Nos.) is assigned to a corresponding one of the 8-bit selection signal combinations.

“0” is set in each of the 8 bits of the selection signal corresponding to the delay No. 0. Each of the coarse adjustment selection signals corresponding to delay numbers 0 to 4 is fixed to “0”, and the five bits of the fine adjustment selection signal are sequentially switched to “1” from the leftmost bit to the rightmost bit.

This is because a signal turning point is sequentially shifted from the output terminal of the inverter 11 toward the output terminal of the inverter 15 in the delay adjustment circuit 10 for fine adjustment (see FIG. 1A) in a state in which the delay adjustment circuit 50 for coarse adjustment (see FIG. 1B) is set such that the signal is constantly returned at the selector 61 in a fixed manner.

Note that a delay time assigned by the selection signal of the delay No. 0 is 120 ps obtained by adding 20 ps in the delay adjustment circuit 10 to 100 ps in the delay adjustment circuit 50. Since an amount of delay is increased by 20 ps every time the delay number is incremented by one in the delay adjustment circuit 10 for fine adjustment, the delay time assigned by the selection signal of the delay No. 4 is 200 ps.

Further, in the delay No. 5 of the selection signal, the leftmost bit of the coarse adjustment three bits of the selection signal is switched to “1” whereas “0” is set to all the fine adjustment five bits of the selection signal. Hence, a delay time assigned by the selection signal of the delay No. 5 is 220 ps obtained by adding 20 ps in the delay adjustment circuit 10 to 200 ps in the delay adjustment circuit 50.

Thereafter, in the selection signals of the delay numbers subsequent to the delay No. 6, fine adjustment bits and coarse adjustment bits are alternately switched from “0” to “1” in series. Hence, a delay time assigned by the selection signal of the delay No. 14 is 400 ps obtained by adding 100 ps in the delay adjustment circuit 10 to 300 ps in the delay adjustment circuit 50.

Invalid data will not cause any defect; however, high electric power consumption may be required for adjusting the delay times of the comparative examples of the delay adjustment circuits 10 and 50 having no power-saving mechanisms by using the selection signals.

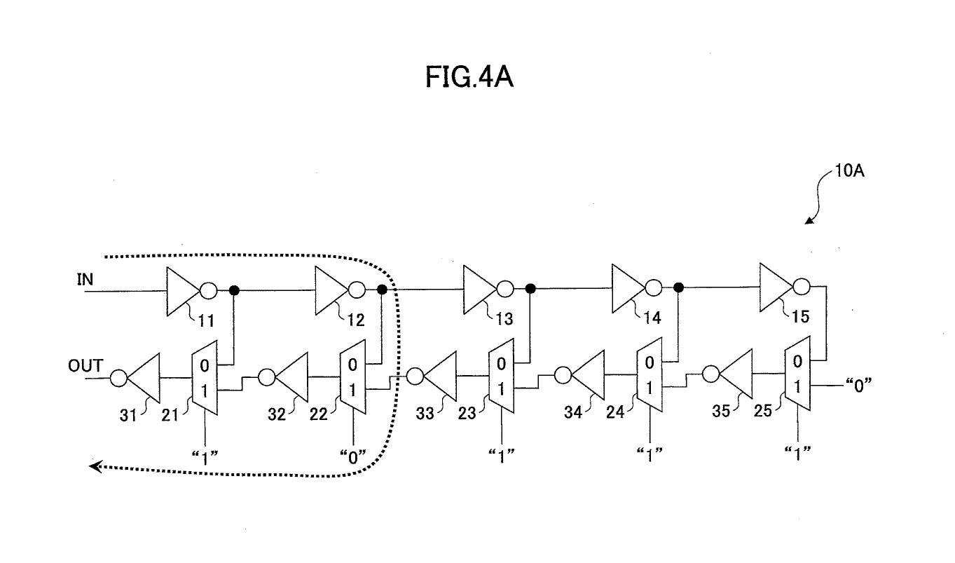

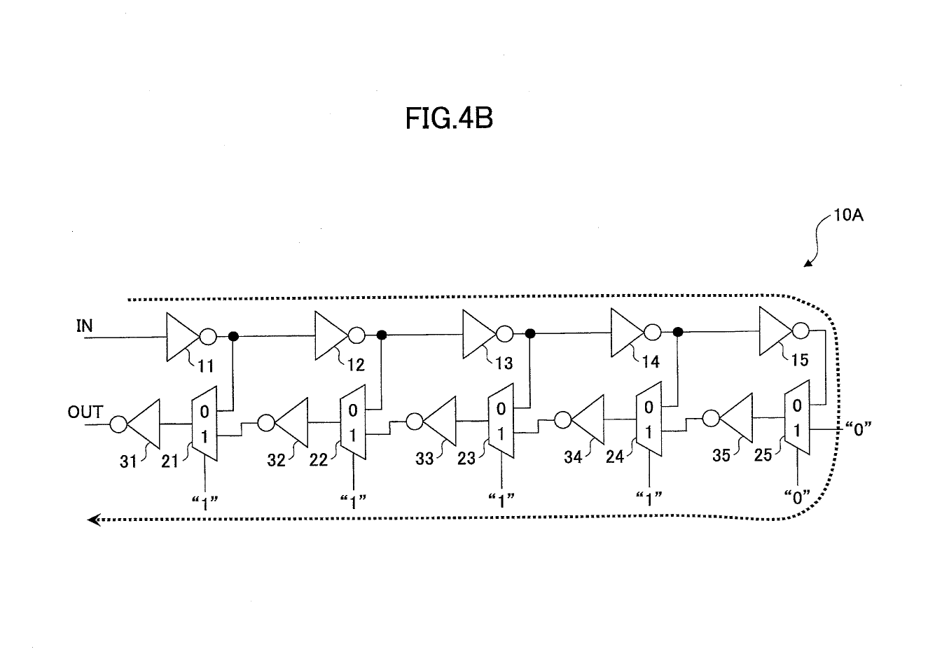

Next, a description will be given, with reference to FIGS. 4A and 4B, of a comparative example of a delay adjustment circuit having a power-saving mechanism to stop the inverters and selectors that are not included in the propagation path of the signal (hereinafter also called a “signal propagation path”).

FIG. 4A is a diagram illustrating a delay adjustment circuit 10A additionally having the power-saving mechanism to stop the inverters and selectors that are not included in the signal propagation path.

The delay adjustment circuit 10A fundamentally includes a circuit configuration similar to that of the comparative example of the delay adjustment circuit 10 illustrated in FIG. 1A, except that fixed data are supplied to one of the input terminals of the selector 25 instead of data X. Note that the fixed data “0” are input into the delay adjustment circuit 10A illustrated in FIG. 4A; however, the fixed data may be “1” to be input into the delay adjustment circuit 10A.

In the comparative example of the delay adjustment circuit 10A having the power-saving mechanism, the selection signal to be supplied to the selectors situated away from the input terminal IN and the output terminal OUT in relation to the selector serving as a signal turning point is set to “1”. This is because data to be supplied to the returning-side inverters and selectors excluded from the signal propagation path are switched from data propagated to the forwarding-side inverters 11 to 15 into fixed data input into the selector 25 so as to stop the operations of the returning-side inverters and selectors to thereby save electric power.

As illustrated in FIG. 4A, when the selectors 21 to 25 of the delay adjustment circuit 10A receive the selection signals “1”, “0”, “1”, “1” and “1”, the signal input into the input terminal IN returns from the selector 22 as indicated by a dotted arrow.

At this time, the selector 25 outputs fixed data, which are propagated to the inverter 35, the selector 24, the inverter 34, the selector 23, and the inverter 33.

Thus, switching operations or the like of transistors of the inverters 33, 34 and 35, and the selectors 23, 24 and 25 may be stopped by inputting fixed data to the inverters 33, 34 and 35, and the selectors 23, 24 and 25 excluded from the signal propagation path.

As a result, the power-saving of the delay adjustment circuit 10A may be achieved.

Thus, the signal input into the input terminal IN changes every second while the switching operations of the inverters 33, 34 and 35, and the selectors 23, 24 and 25 excluded from the signal propagation path are stopped.

However, when the operations of the inverters 33, 34 and 35, and the selectors 23, 24 and 25 are stopped for power-saving, data based on fixed data input into the selectors are constantly output between the output terminal of the selector 25 to the output terminal of the inverter 33.

Such data based on the fixed data input into the selector 25 are invalid data that are unrelated to data of the signal input from the input terminal IN.

Note that it is assumed that such invalid data are output between the output terminal of the selector 25 and the output terminal of the inverter 33. In this case, when the selectors 21 to 25 are supplied with the selection signals “1”, “1”, “1”, “1” and “0” to change the signal turning point from the selector 22 to the selector 25 as illustrated in FIG. 4B, the signal output from the output terminal OUT includes invalid data.

This kind of outcome is observed in a case where the signal turning point is changed from the selector 22 to the selector 23 or the selector 24 while the invalid data are constantly output between the output terminal of the selector 25 and the output terminal of the inverter 33.

Hence, in the comparative example of the delay adjustment circuit 10A having the power-saving mechanism, when the signal turning point is shifted away from the input terminal IN and the output terminal OUT, the signal propagation path includes the inverters and the selectors that hold invalid data. Thus, the signal input into the input terminal IN will not be propagated accurately until the signal reaches the output terminal OUT while the invalid data are propagated within the signal propagation path.

Such a significant defect may be observed specifically when the delay adjustment circuit for coarse adjustment is used, which is obtained by further adding the power-saving mechanism to the comparative example of the delay adjustment circuit 50 (see FIG. 1B) in addition to the delay adjustment circuit 10A illustrated in FIG. 4A.

For example, when the selection signal of the delay No. 5 is changed to the selection signal of the delay No. 4 illustrated in FIG. 3, the signal turning point within the delay adjustment circuit 10A will be shifted from the selector 21 to the selector 25 in a direction away from the input terminal IN and the output terminal OUT simply by reducing the amount of delay by 20 ps.

When the signal turning point is significantly shifted away from the input terminal IN and the output terminal OUT, the signal propagation path includes numerous selectors and returning-side inverters that have deactivated their operations. Hence, numerous invalid data are included in the output signal.

The signal delay device having such the delay adjustment circuit is used for delaying the data signal or a capturing signal to correct a capturing timing of a capturing signal appropriate to the data signal when the signal delay device captures the data signal in the information processing apparatus such as a server.

Hence, the invalid data included in the output signal of the signal delay device may cause a defect in the operations of the information processing apparatus using signals delayed by the delay adjustment circuit. Specifically, an adverse effect on the operations of the information processing apparatus may be greater in the longer signal propagation path having the invalid data than in the shorter signal propagation path having the invalid data.

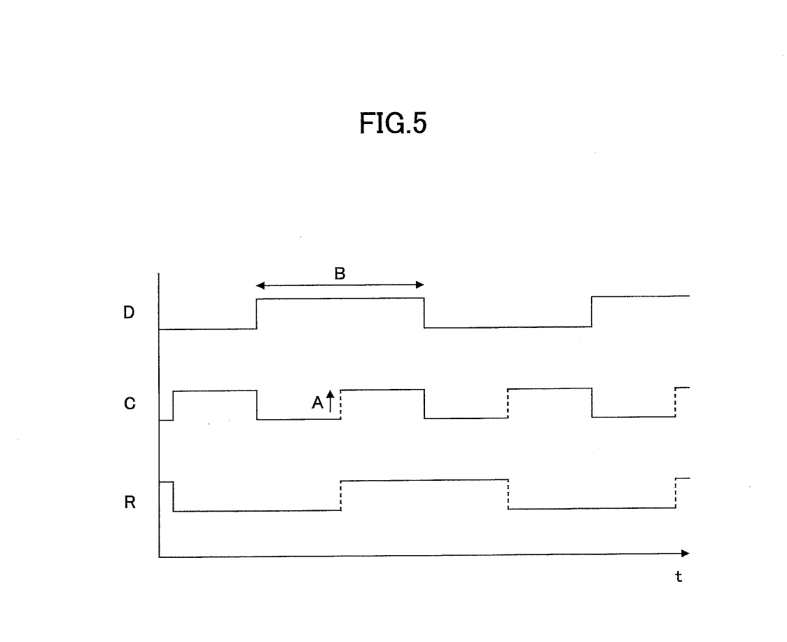

Next, a description is given, with reference to FIGS. 5 to 8, of operations to capture the data signal.

FIGS. 5 to 8 are timing charts illustrating operations when a data signal is captured. In FIGS. 5 to 8, D (abbreviation for Data) represents a data signal, C (abbreviation for Capture) represents a capturing signal, and R (abbreviation for Result) represents a resulting signal of the capturing signal. Note that a horizontal line corresponds to a time axis a right direction of which indicates a time progress direction.

Note that the data signal D is captured by the rise of the capturing signal C. The cycle of the capturing signal C illustrated in FIG. 5 is set to the half the cycle of the data signal D as an example.

In order for the capturing signal C to reliably capture the data signal D, the rise of the capturing signal C indicated by an arrow A is adjusted such that the rise of the capturing signal C is situated near the center of a period B representing the data signal D being at a high (H) level. The above adjustment may be achieved by delaying the data signal D or the capturing signal C.

The resulting signal R representing a result of the capturing signal captures the data signal D at a timing of the rise of the capturing signal C. As a result, the resulting signal R is a signal having accurately captured the data signal D in the example of FIG. 5.

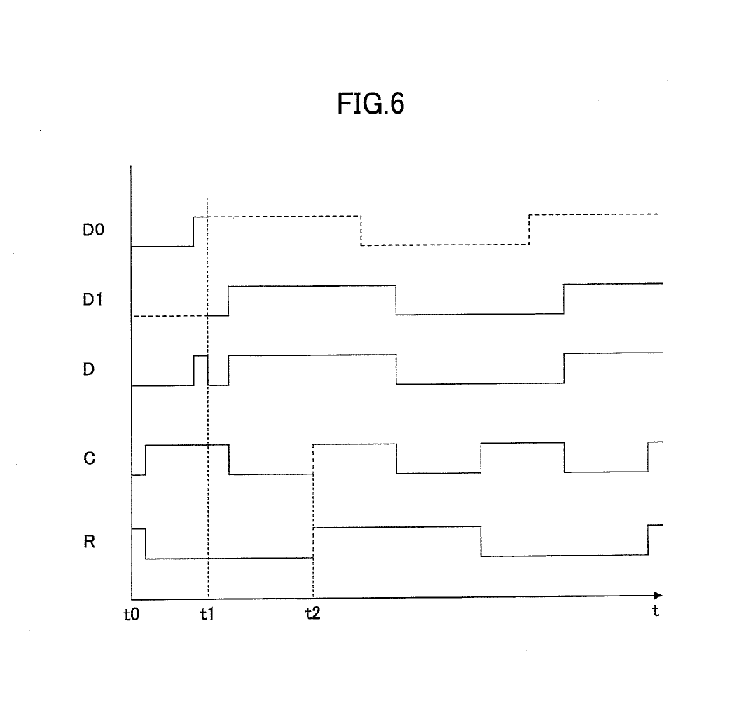

Next, a description will be given, with reference to FIG. 6, of operations to capture the data signal when the amount of delay is increased in the delay adjustment circuit 10 illustrated in FIG. 1. Note that the delay adjustment circuit 10 does not include the power-saving mechanism.

D0 represents the data signal output from the output terminal OUT when the delay adjustment circuit 10 (see FIG. 1A) is supplied with the selection signals “1”, “0”, “0”, “0” and “0”. D1 represents the data signal output from the output terminal OUT when the delay adjustment circuit 10 (see FIG. 1A) is supplied with the selection signals “1”, “1”, “0”, “0” and “0”. Since the data signal D1 includes the amount of delay greater than the amount of delay included in the data signal D0, the waveform of the data signal D1 is shifted in a right direction compared to the waveform of the data signal D0.

When the delay adjustment circuit 10 (see FIG. 1A) is supplied with the selection signals “1”, “0”, “0”, “0” and “0” at time t0, the data signal D is equal to the data signal D0.

In this case, the center of the period where the data signal D0 is at H level comes quicker than the rise of the capturing signal C, and hence, the data signal D0 may need to be delayed.

Hence, when the selection signals “1”, “0”, “0”, “0” and “0” are switched to “1”, “1”, “0”, “0” and “0” at time t1, the data signal D is switched to the data signal D1 having the amount of delay greater than the amount of delay included in the data signal D0. The data signal D includes a waveform obtained by synthesizing the data signal D0 at times t0 to t1 and the data signal D1 after time t1.

Since the data signal D0 is at H level and the data signal D1 is at a low (L) level at time t1 where the amount of delay is switched, the data signal D includes a glitch representing the data signal D being at H level in a cycle shorter than the cycle of the data signal D immediately before the time t1.

However, the center of the period where the data signal D is at H level is approximately situated at the center of the capturing signal C after the time t1. Hence, even though the data signal D is captured at time t2, the glitch residing near the rise of the data signal D will not be incorporated into the resulting signal R representing the capturing result.

Hence, in the example of FIG. 6, the resulting signal R includes a signal waveform representing a result of accurately capturing the data signal D.

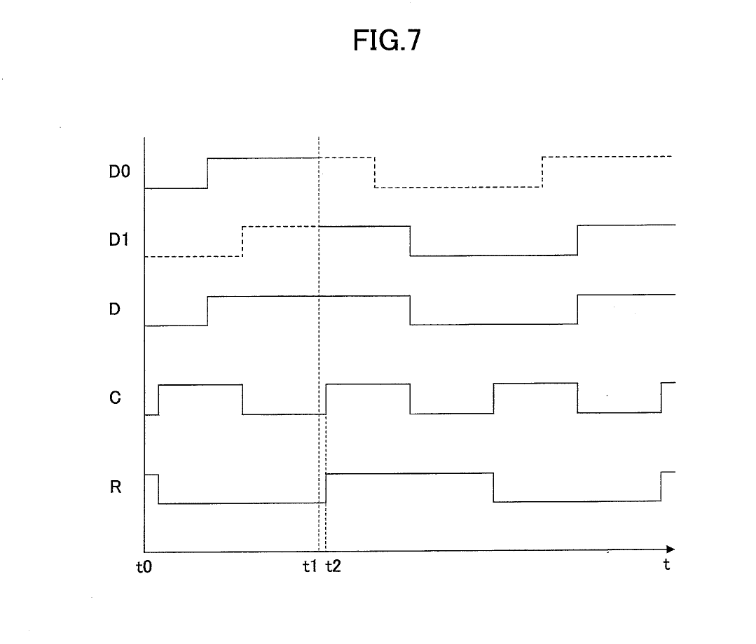

Next, a description will be given, with reference to FIG. 7, of an operations example when the timing (t1) to switch the amount of delay and the timing (t2) to capture the data signal D are closer than the timing (t1) and the timing (t2) of the operations example illustrated in FIG. 6.

Note that the operations example illustrated in FIG. 7 illustrates a case in which the amount of delay is increased in the delay adjustment circuit 10 illustrated in FIG. 1 similar to a case of the operations example illustrated in FIG. 6. Further, the delay adjustment circuit 10 does not include the power-saving mechanism.

In addition, the data signals D0 and D1 illustrated in FIG. 7 are identical to the data signals D0 and D1 illustrated in FIG. 6.

When the delay adjustment circuit 10 (see FIG. 1A) is supplied with the selection signals “1”, “0”, “0”, “0” and “0” at time t0, the data signal D is equal to the data signal D0.

Hence, when the selection signals are switched to “1”, “1”, “0”, “0” and “0” at time t1, the data signal D is switched to the data signal D1 having the amount of delay greater than the amount of delay included in the data signal D0. The waveform of the data signal D becomes a waveform obtained by synthesizing the waveforms of the data signal D0 at times t0 to t1 and the waveforms of the data signal D1 at times subsequent to time t1.

The data signal D0 and D1 are at H level at time t1 after the amount of delay is switched. Hence, the data signal D does not include a glitch.

Next, the data signal D is captured by the rise of the capturing signal C at time t2. The rise of the capturing signal C has a sufficient time with respect to the times at the rise and the fall of the data signal D.

As a result, in the example of FIG. 7, the resulting signal R includes a signal waveform obtained as a result of accurately capturing the data signal D.

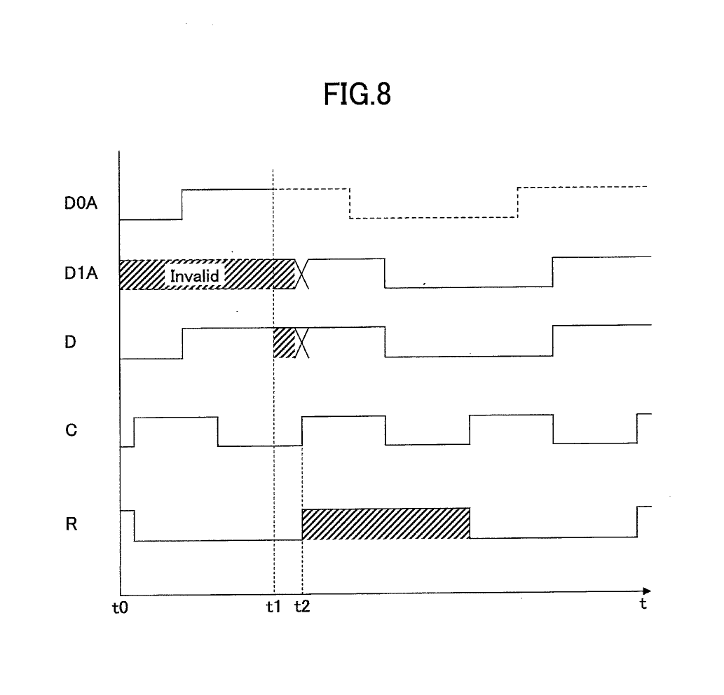

Next, a description will be given, with reference to FIG. 8, of an operations example of the signal delay circuit 10 having the power-saving mechanism illustrated in FIGS. 4A and 4B.

The data signal DOA illustrated in FIG. 8 has a waveform identical to that of the data signal D0 illustrated in FIGS. 6 and 7. The data signal DOA represents the data signal output from the output terminal OUT when the delay adjustment circuit 10A (see FIG. 4A) is supplied with the selection signals “1”, “0”, “1”, “1” and “1”.

Further, the data signal D1A represents the data signal output from the output terminal OUT immediately after the selection signals supplied to the delay adjustment circuit 10A (see FIG. 4A) are switched from “1”, “0”, “1”, “1” and “1” to “1”, “1”, “0”, “1” and “1”. Since the data signal D1A corresponds to data immediately after the signal turning point is shifted away from the input terminal IN and the output terminal OUT, the data signal D1A has invalid data included in the signal propagation path between the output terminal of the selector 23 to the output terminal of the inverter 33 illustrated in FIG. 4A. In FIG. 8, the period in which the invalid data are output is indicated as “Invalid”.

Note that the amount of delay of the data signal D1A with respect to the data signal DOA is equal to the amount of delay of the data signal D1 with respect to the data signal D0 illustrated in FIGS. 6 and 7.

When the delay adjustment circuit 10A (see FIG. 4A) is supplied with the selection signals “1”, “0”, “1”, “1” and “1” at time t0, the data signal D is equal to the data signal DOA.

When the selection signals are switched to “1”, “1”, “0”, “1” and “1” at time t1, the data signal D is switched to the data signal D1A having the amount of delay greater than the amount of delay included in the data signal DOA. However, the data signal D includes a part of the invalid data of the data signal D1A.

Subsequently, the resulting signal R representing a result of the capturing signal captures the data signal D at the rise of the capturing signal C at time t2. As a result, the resulting signal R may result in capturing the invalid data included in the data signal D.

When the signal turning point is shifted away from the input terminal IN and the output terminal OUT in the delay adjustment circuit 10A (see FIG. 4A) having the power-saving mechanism, the data signal output from the output terminal OUT includes invalid data.

Hence, when the comparative example of the signal delay device having the delay adjustment circuit 10A is used in the information processing apparatus such as a server or the like, and such an information processing apparatus captures the data signal having the amount of delay adjusted in the delay adjustment circuit 10A, the resulting signal R representing the result of the capturing signal may include the invalid data.

In the semiconductor circuit device such as LSI fabricated by the semiconductor manufacturing technology, power consumption tends to increase due to an increase in the circuit size as a result of microfabrication. On the other hand, it may be desirable to reduce the power consumption of the LSI in terms of cooling of the LSI, environmental factors, or battery duration.

Hence, in the signal delay device that has achieved the power saving, the selection signals are supplied such that the delay elements excluded from the signal propagation path among a plurality of delay elements for generating delay are stopped (deactivated) similar to the comparative example of the signal delay device having the power-saving mechanism. Accordingly, the electric power consumption may be reduced.

However, in the comparative example of the delay adjustment circuit having the power-saving mechanism, when the signal turning point is shifted away from the input terminal IN and the output terminal OUT, the output data include invalid data, which may disable obtaining accurate output signals.

Further, when the output signal include invalid data, an information processing apparatus such as a server or the like having the signal delay device may exhibit degraded operating behavior.

Accordingly, first and second embodiments described below may provide a signal delay device and a control method of the signal delay device that overcome limitations and disadvantages of the comparative example of the above-described signal delay device and the control method of the signal delay device. In the following, a description will be given of the signal delay device of the first and the second embodiments, and a control method of the signal delay device.

### First Embodiment

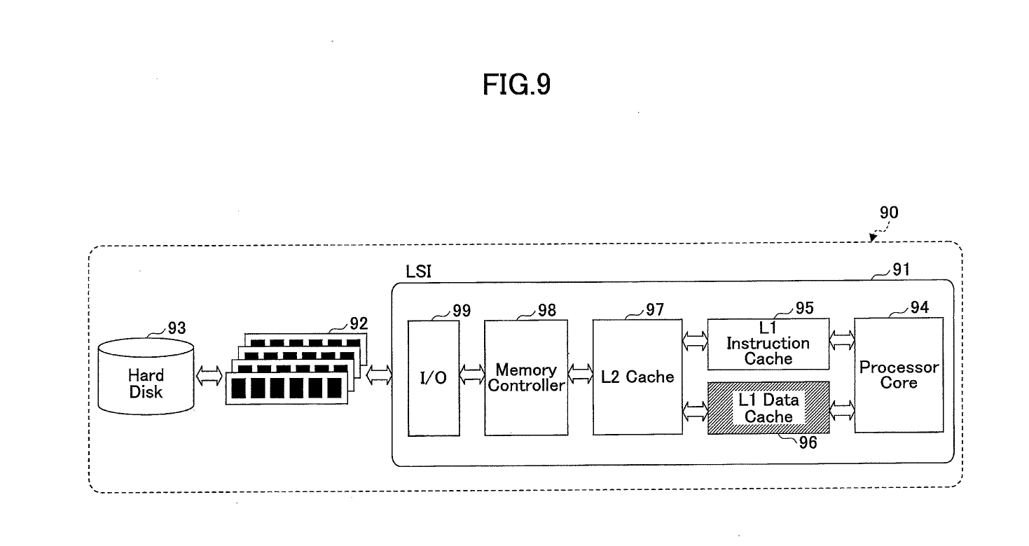

FIG. 9 is a diagram illustrating an information processing apparatus including a signal delay device 100 of a first embodiment.

In the first embodiment, a description will be given of an example of an information processing apparatus that serves as a server 90.

As illustrated in FIG. 9, the server 90 includes a large scale integrated circuit (LSI) 91, a main storage device 92, and a magnetic disk device 93. An interval between the LSI 91 and the main storage device 92, and an interval between the main storage device 92 and the magnetic disk device 93 may, for example, be connected by designated buses, respectively.

The LSI 91 includes processor core 94, a level 1 (L1, primary) instruction cache 95, a L1 data cache 96, a level 2 (L2, secondary) cache 97, a memory controller 98, and input/output (I/O) port 99.

The processor core 94 may, for example, be a central processing unit (CPU) core serving as an arithmetic processing unit configured to perform arithmetic processing of the server 90 as the information processing apparatus. Note that the processor core 94, the L1 instruction cache 95, and the L1 data cache 96 may be integrated as a CPU. There may be two or more processor cores 94. In such a case, each of the processor cores 94 may include one L1 instruction cache 95 and one L1 data cache 96.

The L1 instruction cache 95 is a primary instruction cache configured to temporarily store instructions necessary for arithmetic processing of the processor core 94. The L1 instruction cache 92 may, for example, be formed of an SRAM.

The L1 data cache 96 is a cache memory configured to temporarily store data necessary for the arithmetic processing of the processor core 94, or data generated as a result of the arithmetic processing.

The L2 cache 97 is a cache close to a main storage device 92 and located at a level lower than the L1 instruction cache 95 and the L1 data cache 96 in the memory hierarchical structure. The L2 cache 94 typically has a processing speed lower than those of the L1 instruction cache 95 and the L1 data cache 96; however, the L2 cache has large capacity. The L2 instruction cache 97 may, for example, be formed of an SRAM.

The memory controller 98 is a control device configured to perform control when the LSI performs data read operations or data write operations between the LSI 91 and the main storage device 92. The memory controller 98 may be formed of an LSI.

The I/O port 99 is configured to communicate data (input or output data) between the memory controller 98 and the main storage device 92 when the LSI 91 performs data read operations or data write operations between the LSI 91 and the main storage device 92. The I/O port 99 includes the signal delay device of the first embodiment.

The main storage device 92 may, for example, be a dynamic random access memory (DRAM) and a read only memory (ROM), and the magnetic disk device 93 may, for example, be a hard disk.

Note that the server 90 may include a data input/output interface configured to perform communications with external apparatuses.

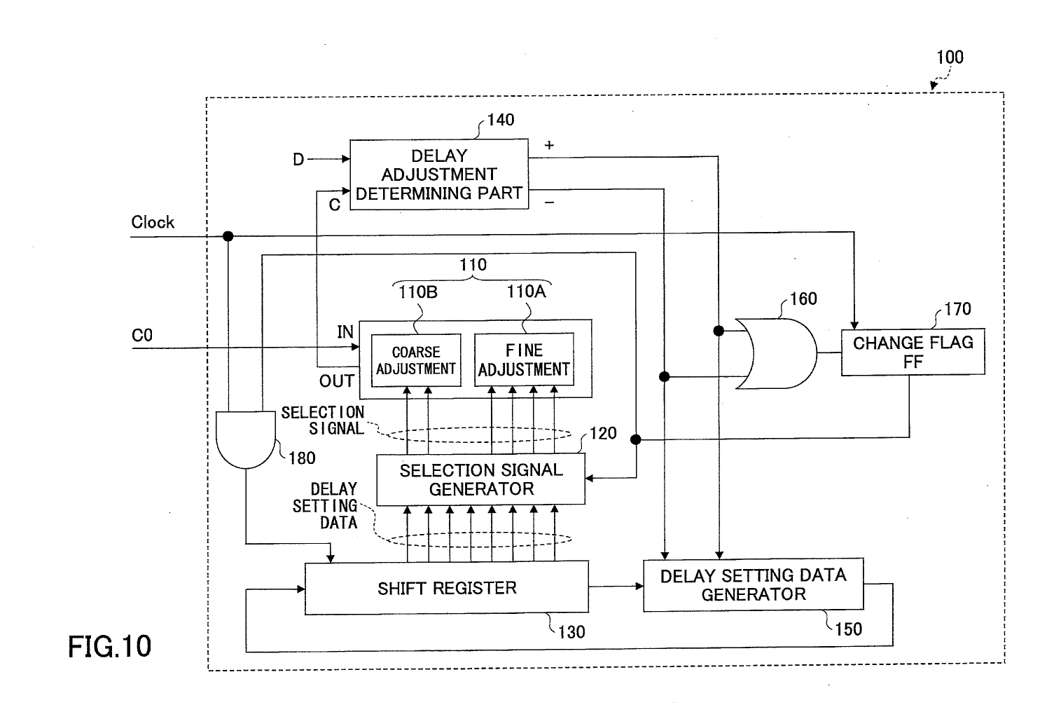

Next, a description will be given of the signal delay device of the first embodiment with reference to FIG. 10.

FIG. 10 is a diagram illustrating the signal delay device 100 of the first embodiment.

The signal delay device 100 of the first embodiment includes a delay adjustment circuit 110, a selection signal generator 120, a shift register 130, a delay adjustment determining part 140, a delay setting data generator 150, an OR (logic operation OR) circuit 160, a change flag FF (flipflop) 170, and an AND (logic operation AND) circuit 180.

The signal delay device 100 of the first embodiment is configured to adjust an amount of delay of a capturing signal C. An original signal C0 of the capturing signal is supplied to the signal delay device 100 to adjust the amount of delay of the supplied capturing signal.

The delay adjustment circuit 110 includes a delay adjustment circuit 110A for fine adjustment and a delay adjustment circuit 110B for coarse adjustment such that a delay (positive delay or negative delay) is assigned to the original signal C0 of the capturing signal supplied to the input terminal IN, and a capturing signal C is output from the output terminal OUT. That is, the original signal C0 of the capturing signal is an example of the input signal input into the signal delay device 100, and the capturing signal C is an example of a delay signal of the signal delay device 100.

The delay adjustment circuit 110A for fine adjustment is fundamentally similar to the delay adjustment circuit 10 for fine adjustment of the comparative example of the signal delay device (see FIG. 1A). Hence, the delay adjustment circuit 110A includes four stages of forwarding-side inverters, four stages of selectors, and four stages of returning-side inverters. The forwarding-side inverters and the returning-side inverters are examples of delay parts connected in series. Further, the selectors are examples of selectors configured to output a delay signal of any of the inverters.

Further, the delay adjustment circuit 110B for coarse adjustment includes two stages of forwarding-side inverters, two stages of selectors, and two stages of returning-side inverters. The delay adjustment circuit 110B for coarse adjustment has an adjustable amount of delay range of the amount of delay greater than the delay adjustment circuit 110A for fine adjustment. However, the delay adjustment circuit 110B for coarse adjustment includes the numbers of the forwarding-side inverters, the selectors, and the returning-side inverters simply differing from those of the delay adjustment circuit 110A for fine adjustment. Hence, the circuit configuration of the delay adjustment circuit 110B for coarse adjustment is fundamentally similar to that of the delay adjustment circuit 110A for fine adjustment.

Note that the numbers of the forwarding-side inverters, the selectors, and the returning-side inverters are not necessarily the same between the forwarding-side inverters, the selectors, and the returning-side inverters. For example, one selector may be provided with respect to a plurality of the forwarding-side inverters. Likewise, one selector may be provided with respect to a plurality of the returning-side inverters. Further, the delay adjustment circuit 110A or 110B may have a circuit configuration that includes either the forwarding-side inverters or the returning-side inverters.

Note that a total number of the forwarding-side inverters and the returning-side inverters needs to be an even number. When the total number of the forwarding-side inverters and the returning-side inverters is not an even number, a polarity of a signal input into the input terminal IN and a signal output from the output terminal OUT may be inverted.

The delay adjustment circuit 110A for fine adjustment (hereinafter also called “fine delay adjustment circuit 110A”) and the delay adjustment circuit 110B for coarse adjustment (hereinafter also called “coarse delay adjustment circuit 110B”) are connected in series. Hence, the delay adjustment circuit 110B for coarse adjustment assigns a coarse delay to the signal input from the input terminal IN, and the delay adjustment circuit 110A further assigns a fine delay so as to output the signal assigned with the coarse and fine delays from the output terminal OUT.

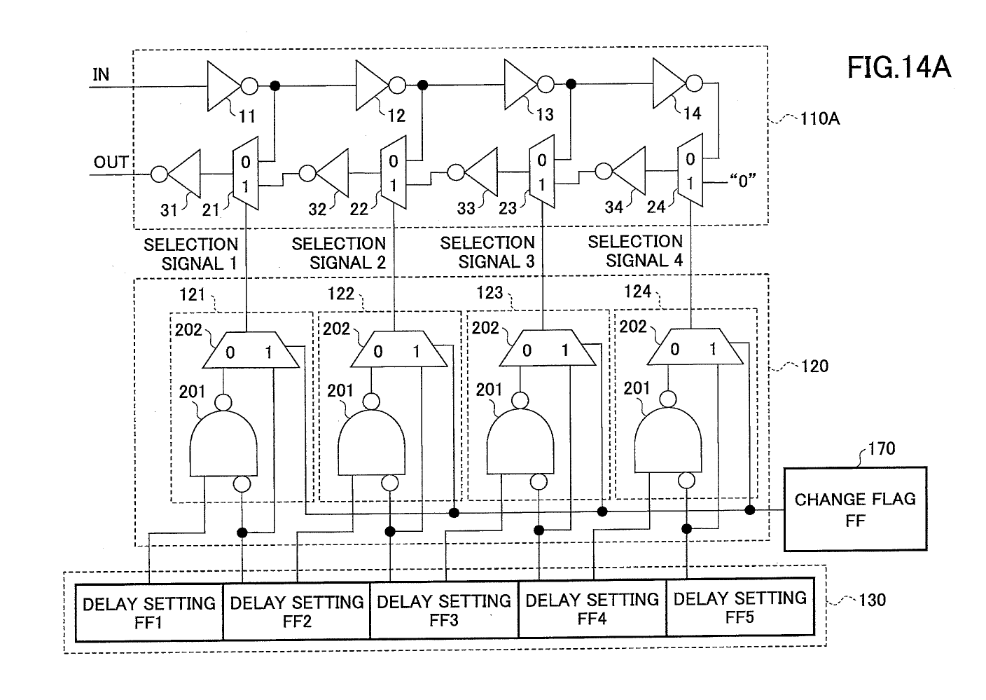

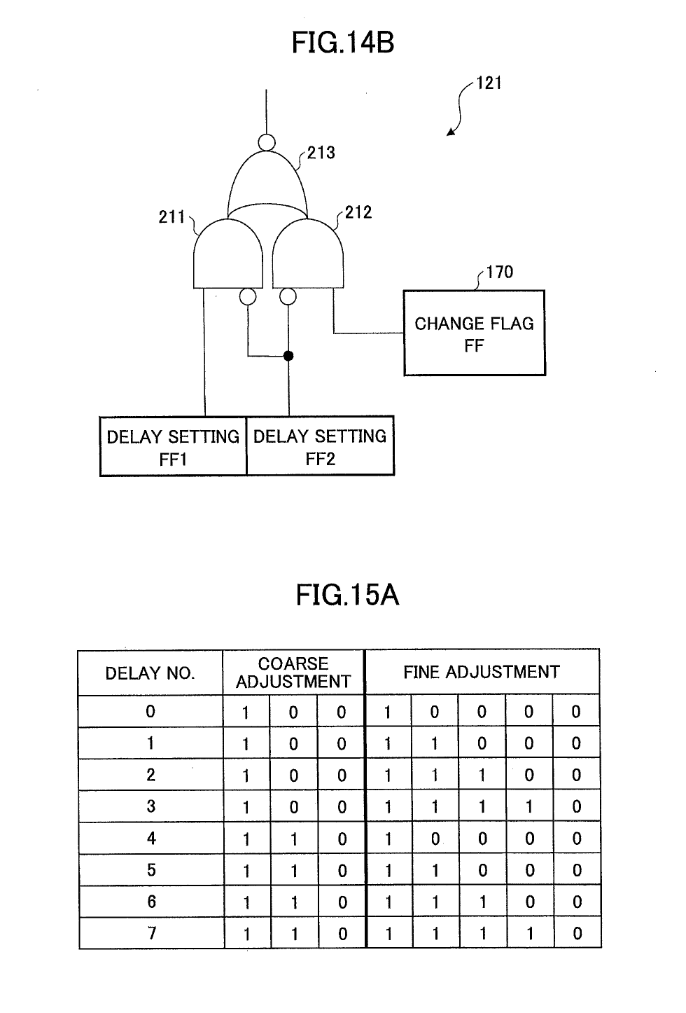

Note that detailed description of the circuit configuration of the delay adjustment circuit 110 of the first embodiment will be given later with reference to FIGS. 14A and 14B.

The selection signal generator 120 is configured to generate a selection signal to be supplied to the delay adjustment circuit 110 based on delay setting data held by the shift register 130. Note that detailed descriptions of the circuit configuration of the selection signal generator 110 will be given later with reference to FIGS. 14A and 14B.

The shift register 130 is an example of a data holding part configured to hold delay setting data set by the delay setting data generator 150.

Note that the delay setting data are set in the shift register 130 in order to determine a value of the selection signal generated by the selection signal generator 120, and the delay setting data generator 150 sets the delay setting data for adjusting the amount of delay in the delay adjustment circuit 110. The delay setting data include fine adjustment delay setting data and coarse adjustment delay setting data. Each of the fine adjustment delay setting data and the coarse adjustment delay setting data has a bit range obtained by adding one to the number of selectors included in a corresponding one of the delay adjustment circuits 110A and 110B.

Hence, the fine adjustment delay setting data has five bits whereas the coarse adjustment delay setting data has three bits. Hence, the shift register 130 is configured to output 8-bit delay setting data.

The shift register 130 is supplied with an output signal of the AND circuit 180. The delay setting data held by the shift register 130 are updated when the output signal of the AND circuit 180 is switched to “1”.

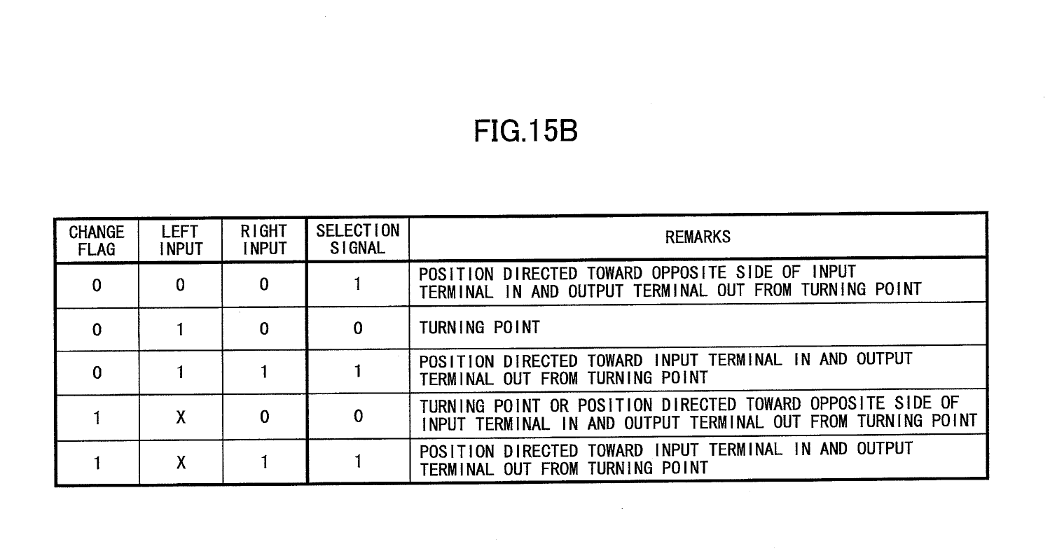

Note that descriptions of the shift register 130 and the delay setting data will be given later with reference to FIGS. 14A and 14B, and FIGS. 15A and 15B.

The delay adjustment determining part 140 is configured to compare a phase of the data signal D and a phase of the capturing signal C, determine whether the amount of delay needs to be increased (+) or decreased (−), or whether the adjustment of the amount of delay is unnecessary, and output a judgment result.

The delay adjustment determining part 140 is further configured to output the judgment result representing a delay increase signal (+) or a delay decrease signal (−). Note that the judgment result including “1” (H level) of the delay increase signal (+) and “0” (L level) of the delay decrease signal (−) indicates that the amount of delay needs to be increased.

The judgment result including “0” (L level) of the delay increase signal (+) and “1” (H level) of the delay decrease signal (−) indicates that the amount of delay needs to be decreased.

The judgment result including “0” (L level) of the delay increase signal (+) and “0” (L level) of the delay decrease signal (−) indicates that the amount of delay need not be increased or decreased.

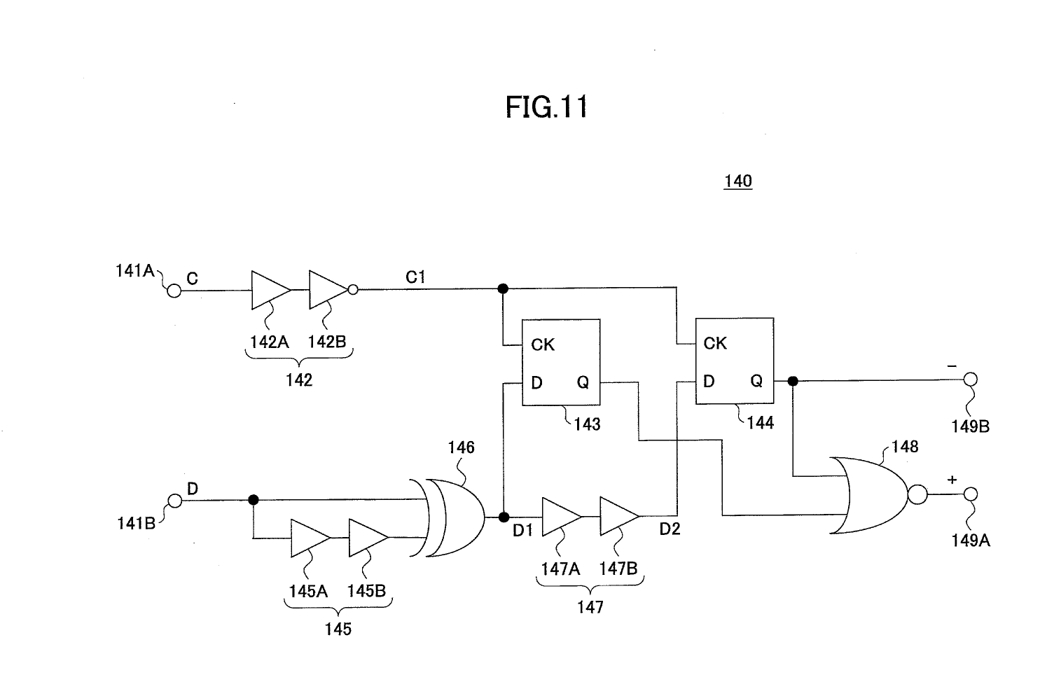

Note that a detailed description of the circuit configuration of the delay adjustment determining part 140 will be given later with reference to FIG. 11.

The delay setting generator 150 is supplied with the delay increase signal (+) or the delay decrease signal (−) output from the delay adjustment determining part 140. The delay setting data generator 150 is configured to generate delay setting data having reflected contents of the delay increase signal (+) and the delay decrease signal (−) based on the delay increase signal (+) and the delay decrease signal (−), and the delay setting data currently set in the shift register 130.

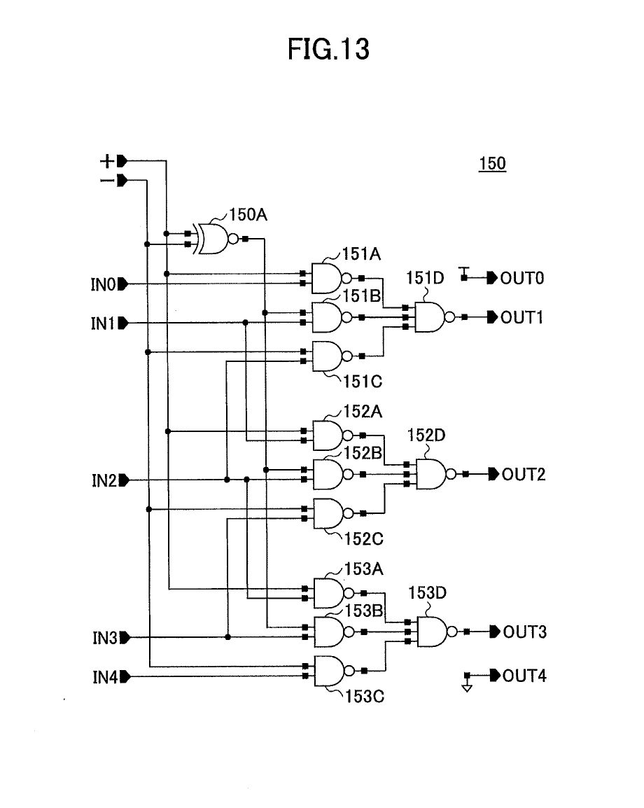

Note that a detailed description of the circuit configuration of the delay setting data generator 150 will be given later with reference to FIG. 13.

The OR circuit 160 is configured to output logical OR (OR) of the delay increase signal (+) or the delay decrease signal (−) output from the delay adjustment determining part 140. The output of the OR circuit 160 is “1” when one of the values of the delay increase signal (+) and the delay decrease signal (−) is “1”. The output of the OR circuit 160 is supplied to the change flag FF 170.

The change flag FF 170 is configured to set the change flag at the rise of the clock based on the output of the OR circuit 160. The change flag FF 170 is an example of an OR holder configured to hold an arithmetic operation result of the OR circuit 160 serving as a logic operation OR circuit.

The change flag serves as a flag used for changing a signal turning point in the delay adjustment circuit 110. The change flag has a setting of “0” (L level: OFF) when the signal turning point is not switched, and has a setting of “1” (H level: ON) when the signal turning point is switched.

The change flag is switched to “1” (H level: ON) when one of the values of the delay increase signal (+) and the delay decrease signal (−) is “1”. Further, the change flag is switched to “0” (L level: OFF) when the values of the delay increase signal (+) and the delay decrease signal (−) are both “0”. The change flag is supplied to the selection signal generator 120 and the AND circuit 180.

Further, the signal delay device 100 of the first embodiment switches ON the power-saving mechanism when the change flag is “0” (OFF), and switches OFF the power-saving mechanism when the change flag is “1” (ON).

The power saving-mechanism is switched ON of OFF in accordance with the selection signal set based on the delay setting data and the change flag. The ON/OFF of the power-saving mode in the signal delay device 100 of the first embodiment will be will be described later with reference to FIGS. 15A and 15B.

The AND circuit 180 is configured to receive the clock and the change flag, and output logical AND of a value determined based on the clock level and a value of the change flag. The output of the AND circuit 180 is supplied to the shift register 130. The delay setting data held by the shift register 130 are updated with new delay setting data generated by the delay setting data generator 150 when the output signal of the AND circuit 180 is switched to “1”.

In the signal delay device 100 of the first embodiment, when the delay adjustment determining part 140 determines that the amount of delay of the capturing signal C needs to be increased and outputs one of the delay increase signal (+) and the delay decrease signal (−), the delay setting data generator 150 generates new delay setting data. Further, when the delay adjustment determining part 140 outputs one of the delay increase signal (+) and the delay decrease signal (−), the change flag FF 170 raises the change flag along with the rise of the clock.

The change flag is supplied to the selection signal generator 120 while being supplied to a first input terminal of the AND circuit 180. When the H level change flag is input into the selection signal generator 120, the signal delay device 100 switches OFF the power-saving mechanism of the delay adjustment circuit 110. The signal delay device 100 switches OFF the power-saving mechanism for resetting the selection signal as preparation to switch the signal turning point.

Hence, since the selection signal is reset by switching ON the change flag, the adverse effect due to the invalid data may be eliminated. When a next clock rises after the change flag has been switched ON, the H level clock is input into a second input terminal of the AND circuit 180 and an output of the AND circuit 180 is “1”. Hence, the delay setting data held by the shift register 130 are updated with new delay setting data.

The delay setting data held by the shift register 130 are updated when the output signal of the AND circuit 120 is switched to “1”. Accordingly, the signal turning point in the delay adjustment circuit 110 is changed, and the capturing signal C, the amount of delay of which is adjusted, is output from the output terminal OUT of the delay adjustment circuit 110 as a signal for capturing a data signal D into the delay adjustment determining part 140.

As described above, the signal delay device 100 switches OFF the power-saving mechanism when the change flag rises along with the rise of a certain clock. The signal delay device 100 switches OFF the power-saving mechanism when the change flag rises for having a preparation period to eliminate the invalid data within the delay adjustment circuit 110 until the next clock rises, provided that the invalid data are present within the delay adjustment circuit 110.

The signal delay device 100 changes the signal turning point when the output of the AND circuit 180 is switched to “1” along with the rise of the next clock, and outputs the capturing signal C, the amount of delay of which is adjusted, from the output terminal OUT of the delay adjustment circuit 110.

The signal delay device 100 of the first embodiment has an interval of one clock cycle, from a time where the delay adjustment determining part 140 determines that the amount of delay of the capturing signal C needs to be increased or decreased and has raised the change flag, to a time where the signal turning point in the delay adjustment circuit 110 is changed.

The interval of one clock cycle is provided as a preparation period for eliminating the invalid data generated by the power-saving mechanism within the delay adjustment circuit 110. The OR circuit 160, the change flag FF 170, and the AND circuit 180 are an example of a preparation period setting part for setting the preparation period.

Next, a description will be given, with reference to FIG. 11, of a circuit configuration and operations of the delay adjustment determining part 140 of the signal delay device of the first embodiment.

FIG. 11 is a diagram illustrating a circuit configuration of a delay adjustment determining part 140 of the signal delay device 100 of the first embodiment.

The delay adjustment determining part 140 includes input terminals 141A and 141B, a delay part 142, FFs 143 and 144, a delay part 145, an exclusive OR (XOR) circuit 146, a delay part 147, a negative OR (NOR) circuit 148, and output terminals 149A and 149B.

The input terminal 141A is connected to the delay part 142. The delay part 142 is supplied with the capturing signal C from the input terminal 141A.

The delay part 142 includes a buffer 142, and an inverter 142B. The output terminal of the delay part 142 is connected to a clock input terminal CK of the FF 143 and a clock input terminal CK of the FF 144. The delay part 142 outputs a signal C1 obtained by assigning a delay to the capturing signal C input from the input terminal 141A.

Note that a delay time assigned by the buffer 142A and the inverter 142B of the delay part 142 may, for example, be set so as to be equal to a total time of a time between a data signal D1 being input into the input terminal 141B and the data signal D being output from the XOR circuit 146, and a setup time of the FF 143.

Note that the setup time represents a time in which the output circuit in the former stage needs to constantly output the data signal to be held in the flipflop in advance.

The FF 143 includes a clock input terminal CK, a data input terminal D, and a data output terminal Q. The clock signal input terminal CK is connected to the output terminal of the delay part 142 such that the clock signal input terminal CK is supplied with the signal C1 output from the delay part 142. The data input terminal D is connected to the output terminal of the XOR circuit 146 such that the data input terminal D is supplied with the data signal D1 output from the XOR circuit 146. The data output terminal Q is connected to a first input terminal of the NOR circuit 148.

The FF 143 captures the data signal D1 output from the XOR circuit 146 into the data input terminal D when the signal C1 input into the clock signal input terminal CK rises. The data captured into the data input terminal D are reflected in the data output terminal Q.

The FF 144 includes a clock input terminal CK, a data input terminal D, and a data output terminal Q. The clock signal input terminal CK is connected to the output terminal of the delay part 142 such that the clock signal input terminal CK is supplied with the signal C1 output from the delay part 142. The data input terminal D is connected to the output terminal of the delay part 147 such that the data input terminal D is supplied with the data signal D2 output from the delay part 147. The data output terminal Q is connected to a second input terminal of the NOR circuit 148 and to an output terminal 149B.

When the FF 144 captures the data signal D2 output from the delay part 147 into the data input terminal D when the signal C1 input into the clock signal input terminal CK rises. The data captured into the data input terminal D are reflected in the data output terminal Q.

The input terminal 141B is connected to the delay part 145, and a first input terminal of the XOR circuit 146. The input terminal 141B is supplied with the data signal D.

The delay part 145 includes buffers 145A and 145B. The output terminal of the delay part 145 is connected to a second input terminal of the XOR circuit 146.

A first input terminal of the XOR circuit 146 is connected to the input terminal 141B, and the second input terminal of the XOR circuit 146 is connected to the output terminal of the delay part 145. The output terminal of the XOR circuit 146 is connected to the data input terminal D of the FF 143 and the input terminal of the delay part 147. The XOR circuit 146 outputs XOR (exclusive OR) of the data signal D input from the input terminal 141B and the data signal D input from the delay part 145.

The first and second input terminals of the XOR circuit 146 are both supplied with the data signal D; however, the data signal D is delayed in an amount corresponding to a delay time of the delay part 145, and the delayed data signal D is supplied to the second input terminal of the XOR circuit 146. Accordingly, when the signal level of the data signal D is switched, respective values of the input data of the first and the second input terminals of the XOR circuit 146 differ from each other during the delay time of the delay part 145. Hence, the XOR circuit 146 outputs a H level (“1”) data signal D1

That is, the delay part 145 and the XOR circuit 146 serve as a rise detection circuit configured to detect the rise of the data input signal D.

The delay part 147 includes buffers 147A and 147B. An output terminal of the delay part 147 is connected to a data input terminal D of the FF 144.

A first input terminal of the NOR circuit 148 is connected to a data output terminal Q of the FF 143, and a second input terminal of the NOR circuit 148 is connected to a data output terminal Q of the FF 144. An output terminal of the NOR circuit 148 is connected to an output terminal 149A. The NOR circuit 148 outputs NOR (negative OR) of a data signal input from the data output terminal Q of the FF 143 and the data output terminal Q of the FF 144.

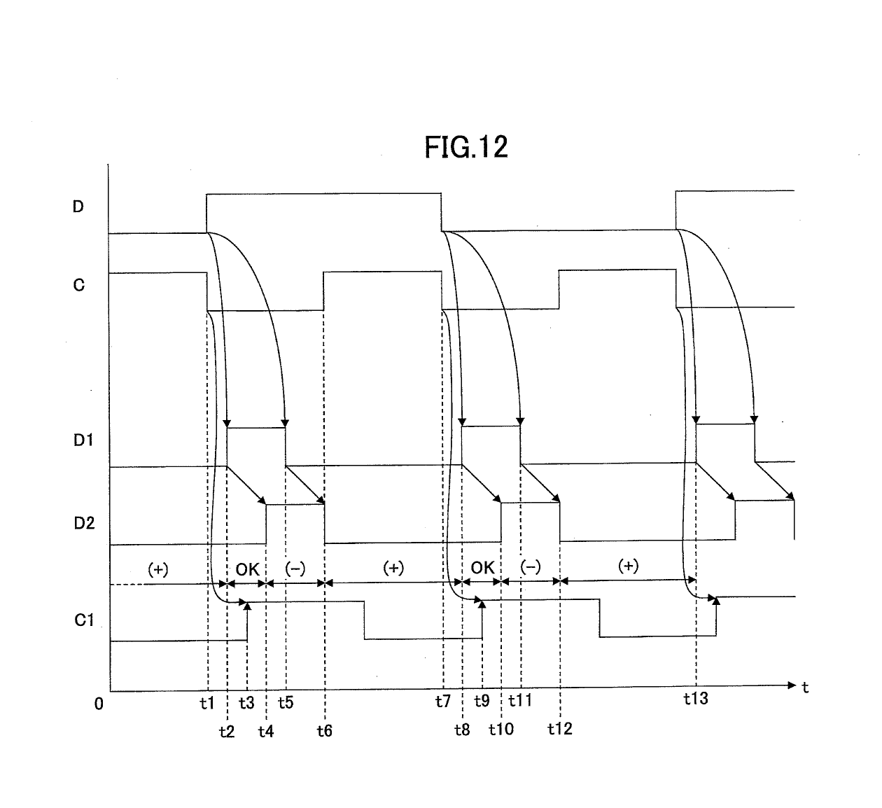

Next, a description will be given, with reference to FIG. 12, of operations of the delay adjustment determining part 140 of the signal delay device of the first embodiment.

FIG. 12 is a timing chart representing the operations of the delay adjustment determining part 140 of the signal delay device of the first embodiment.

A description is given of the data signal D being captured by the rise of the capturing signal C in the first embodiment. The cycle of the capturing signal C illustrated in FIG. 12 is set to half the cycle of the data signal D as an example. In a state where there is no phase difference between the capturing signal C and the data signal D, the rise of the capturing signal C is situated at the center of a period representing the data signal D being at a high (H) level or a period representing the data signal D being at a low (L) level.

At time t1, a phase of the fall of the capturing signal C and a phase of the rise of the data signal D are matched at a timing of the fall of the capturing signal C.

When the data signal D rises to H level (“1”) at time t1, the data signal D input into the first input terminal of the XOR circuit 146 is switched to “1”. Further, the data signal input into the second input terminal of the XOR circuit 146 is switched to “1” after the delay time is assigned to the data signal by the delay part 145. Hence, the XOR circuit 146 outputs the data signal D1 at H level (“1”) in an interval between time t2 and time t5.

A pulse width of the H level (“1”) data signal D1 corresponds to the delay time of the delay part 145.

Further, the data signal D1 is delayed in an amount of the delay time of the delay part 147, and the delayed data signal D1 is output from the delay part 147 as a data signal D2.

Hence, the data signal D2 rises at time t4 and falls at time t6. The time difference between the time t2 and the time t4 corresponds to the delay time of the delay part 147.

On the other hand, when the capturing signal C falls at time t1, the signal C is delayed by the delay part 142 and the delayed signal C is output as a signal C1. Hence, the signal C1 rises at time t3. The time difference between the time t1 and the time t3 corresponds to the delay time of the delay part 142.

The above-described operations are similar to the operations after the data signal D falls at time t7, and the operations performed from time t6 to t12 are similar to the operations performed from time t1 to time t6.

When the FF 143 and FF 144 capture the data signals D1 and D2, respectively, the output value of the data output terminal Q of the FF 144 is reflected in the output terminal 149B, and the output value of the NOR circuit 148 is reflected in the output terminal 149A as the output of the NOR circuit 148 is determined.

The output terminal 149A outputs a delay increase signal (+) representing a determining result indicating that the amount of delay needs to be increased (+), and the output terminal 149B outputs a delay decrease signal (−) representing a determining result indicating that the amount of delay needs to be decreased (−).

When the delay increase signal (+) and the delay decrease signal (−) are both “0”, a determining result indicates that the amount of delay of the capturing signal C need not be adjusted (OK).

When the delay increase signal (+) is “1” and the delay decrease signal (−) is “0”, a determining result indicates that the amount of delay of the capturing signal C needs to be increased (+).

When the delay increase signal (+) is “0” and the delay decrease signal (−) is “1”, a determining result indicates that the amount of delay of the capturing signal C needs to be decreased (−).

As described above, when the rise of the capturing signal C is situated at the center of the period where the data signal D1 is at H level or at the center of the period where the data signal D2 is at H level, the rise of the signal C1 is situated in an interval between the rise of the data signal D1 and the rise of the data signal D2.

At this time, the data output terminal Q of the FF 144 outputs “0”, and the NOR circuit 148 outputs “0”. Likewise, the data output terminal Q of the FF 144 outputs “0”, and the NOR circuit 148 outputs “0” when the rise of the signal C1 is situated in an interval between time t2 and time t4.

Hence, the amount of delay of the capturing signal C need not be adjusted in the period where the rise of the signal C1 is situated in an interval between time t2 and time t4.

Further, the data signal D2 is switched to H level (“1”) in an interval between time t4 and time t6. The value of the data signal D2 is reflected in the output terminal 149B via the FF 144. That is, the output value of the output terminal 149B is “1”. Further, the output of the NOR circuit 148 is “0” and the output value of the output terminal 149A is “0” in an interval between time t4 and time t6.

Hence, the amount of delay of the capturing signal C needs to be decreased (−) in the interval between time t4 and time t6.

Further, since the data signals D1 and D2 are both switched to L level (“0”) in an interval between time t6 and time t8, the output of the NOR circuit 148 is “1”. That is, the output value of the output terminal 149A is “1”. Further, since the data signal D2 is “0”, the data output terminal Q of the FF 144 outputs a L level (“0”) signal. That is, the output value of the output terminal 149B is “0”.

Hence, the amount of delay of the capturing signal C needs to be increased (+) in the interval between time t6 and time t8.

As described above, the delay adjustment determining part 140 compares the phase of the data signal D and the phase of the capturing signal C, determines whether the amount of delay needs to be increased (+) or decreased (−), or whether the adjustment of the amount of delay is unnecessary, and outputs a judgment result.

Next, a description will be given, with reference to FIG. 13, of a circuit configuration and operations of the delay setting data generator 150 of the signal delay device of the first embodiment.

FIG. 13 is a diagram illustrating a circuit configuration of the delay setting data generator 150 of the signal delay device 100 of the first embodiment.

The delay setting generator 150 includes a + terminal and a − terminal configured to be respectively supplied with the delay increase signal (+) or the delay decrease signal (−) output from the delay adjustment determining part 140 (see FIG. 10). Further, the delay setting data generator 150 includes input terminals IN0 to IN4 configured to be respectively supplied with 5 bit delay setting data from the shift register 130 (see FIG. 10), and output terminals OUT0 to OUT4 that respectively output 5 bit delay setting data to the shift register 130.

The delay setting data input from the D0 input terminals IN0 to IN4 represent values of current delay setting data held by the shift register 130 for generating four selection signals to be input into the delay adjustment circuit 110A for fine adjustment. Further, the delay setting data output from the output terminals OUT0 to OUT4 and set in the shift register 130 represent delay setting data to be updated at the rise of the next clock signal.

The delay setting data generator 150 includes a separate circuit differing from the circuit configured to generate 3 bit delay setting data illustrated in FIG. 13 for generating two selection signals input into the delay adjustment circuit 110B for coarse adjustment. Hence, FIG. 13 illustrates a circuit configured to generate delay setting data for generating four selection signals input into the delay adjustment circuit 110A for fine adjustment.

The delay setting data are set as “1” in the input terminals IN0 to IN4 and the output terminals OUT0 to OUT4 that have smaller numerical subscripts, and set as “0” in the input terminals IN0 to IN4 and the output terminals OUT0 to OUT4 that have greater numerical subscripts. A position at which the value of the delay setting data is switched from “1” to “0” corresponds to a signal turning point. That is, the amount of signal delay in the fine delay adjustment circuit 110A is determined based on a position at which the value of the delay setting data is switched from “1” to “0”.

Hence, the value of the input terminal IN0 corresponding to the first bit of the delay setting data and the value of the output terminal OUT0 are fixed to “1”. Further, the value of the input terminal IN4 corresponding to the fifth bit of the delay setting data and the value of the output terminal OUT4 are fixed to “0”. Note that the output terminal OUT0 is connected to H level power supply and the output terminal OUT4 is grounded.

The values of the delay increase signal (+) and the delay increase signal (−) respectively supplied to the + terminal and − terminal represent as follows. When the values of the delay increase signal (+) and the delay increase signal (−) are “1” (H level) and “0” (L level), respectively, the amount of delay is increased. When the values of the delay increase signal (+) and the delay increase signal (−) are “0” (L level) and “1” (H level), respectively, the amount of delay is decreased.

Two-way input NAND (negative AND) circuits 151A, 151B and 151C, and a three-way input NAND (negative AND) circuit 151D are connected between the + terminal, − terminal, input terminals IN0 and IN1, and the output terminal OUT1.

Similarly, two-way input NAND circuits 152A, 152B and 152C, and a three-way input NAND circuit 152D are connected between the + terminal, − terminal, input terminals IN0 and IN1, and the output terminal OUT2.

Two-way input NAND circuits 153A, 153B and 153C, and a three-way input NAND circuit 153D are connected between the + terminal, − terminal, input terminals IN0 and IN1, and the output terminal OUTS.

Further, each of the + terminal and − terminal is connected to a corresponding one of a pair of input terminals of the XNOR (exclusive NOR) circuit 150A. The output terminal of the XNOR circuit 150A is connected to each of the first input terminals of the NAND circuits 151B, 152B and 153B.

The first input terminal of the NAND circuit 151A is connected to the + terminal, and the second input terminal of the NAND circuit 151A is connected to the input terminal IN0. The output terminal of the NAND circuit 151A is connected to a first one of the three input terminals of the NAND circuit 151D.

The first input terminal of the NAND circuit 151B is connected to the output terminal of the XNOR 150A, and the second input terminal of the NAND circuit 151B is connected to the input terminal IN1. The output terminal of the NAND circuit 151A is connected to a second one of the three input terminals of the NAND circuit 151D.

The first input terminal of the NAND circuit 151C is connected to the − terminal, and the second input terminal of the NAND circuit 151C is connected to the input terminal IN2. The output terminal of the NAND circuit 151C is connected to a third one of the three input terminals of the NAND circuit 151D.

The first, second and third input terminals of the NAND circuit 151D are connected to the respective output terminals of the NAND circuits 151A, 151B and 151C, and the output terminal of the NAND circuit 151D is connected to the input terminal OUT1.

The output terminals OUT2 and OUTS are connected to the NAND circuits 152A to 152D, and the NAND circuits 153A to 153D, respectively, in a connection relationship similar to the connection relationship between the output terminal OUT1 and the NAND circuits 151A to 151D. Hence, the descriptions of the respective connection relationships between the NAND circuits 152A to 152D, and between the NAND circuits 153A to 153D are omitted from the specification.

Next, operations of the NAND circuits 151A to 151D are illustrated.

To increase the amount of delay, when the value of the delay increase signal (+) supplied to the + terminal is “1”, and the value of the delay decrease signal (−) supplied to the − terminal is “0”, the output of the XNOR circuit 150A is “0”.

Since the NAND circuit 151A receives the value “1” of the delay increase signal (+) and the value “1” of the input terminal IN0, the NAND circuit 151A outputs “0”.

Since the NAND circuit 151B receives the output “0” of the XNOR circuit 150A and the value of the input terminal IN1, the NAND circuit 151B outputs “1” regardless of the value of the input terminal IN1.

Since the NAND circuit 151C receives the value “0” of the delay decrease signal (−) and the value of the input terminal IN2, the NAND circuit 151C outputs “1” regardless of the value of the input terminal IN2.

As described above, the first, second and third input terminals of the NAND circuit 151D receive “0”, “1” and “1”, respectively, the output of the NAND circuit 151D is “1”. That is, the output value of the output terminal OUT1 is “1”.

Note that the value of the input terminal IN0 is fixed to “0”. Hence, when the value of the input terminal IN1 is “0”, the second bit delay setting data is set to the value “1” of the output terminal OUT1 at the rise of the next clock signal.

As a result, the amount of delay is increased.

Further, to decrease the amount of delay, when the value of the delay increase signal (+) supplied to the + terminal is “0”, and the value of the delay decrease signal (−) supplied to the − terminal is “1”, the output of the XNOR circuit 150A is “0”.

Since the NAND circuit 151A receives the value “0” of the delay increased signal (+) and the value “1” of the input terminal IN0, the NAND circuit 151A outputs “1”.

Since the NAND circuit 151B receives the output “0” of the XNOR circuit 150A and the value of the input terminal IN1, the NAND circuit 151B outputs “1” regardless of the value of the input terminal IN1.

The NAND circuit 151C receives the value “1” of the delay decrease signal (−) and the value of the input terminal IN2. Hence, the NAND circuit 151C outputs “0” when the value of the input terminal IN2 is “1”, and outputs “1” when the value of the input terminal IN2 is “0”.

As described above, the first, second and third input terminals of the NAND circuit 151D receive “1”, “1” and “0”, respectively, so that the output of the NAND circuit 151D is “1”. That is, the output value of the output terminal OUT1 is “1”.

Further, when the value of the input terminal IN2 is “0”, the first, second and third input terminals of the NAND circuit 151D receive “1”, “1” and “1”, respectively. Hence, the output of the NAND circuit 151D is “0”. That is, the output value of the output terminal OUT1 is “0”.

Note that when the value of the input terminal IN1 is “1”, and the value of the input terminal IN2 is “0”, the second bit delay setting data is set to the value “0” of the output terminal OUT1 at the rise of the next clock signal.

As a result, the amount of delay is decreased.

Further, to maintain the amount of delay, when the value of the delay increase signal (+) supplied to the + terminal and the value of the delay decrease signal (−) supplied to the − terminal are both “0”, the output of the XNOR circuit 150A is “1”.

Since the NAND circuit 151A receives the value “0” of the delay increase signal (+) and the value “1” of the input terminal IN0, the NAND circuit 151A outputs “1”.

The NAND circuit 151B receives the value “1” of the XNOR circuit 150A and the value of the input terminal IN1. Hence, the NAND circuit 151B outputs “0” when the value of the input terminal IN1 is “1”, and outputs “1” when the value of the input terminal IN1 is “0”.

Since the NAND circuit 151C receives the value “0” of the delay decrease signal (−) and the value of the input terminal IN2, the NAND circuit 151C outputs “1” regardless of the value of the input terminal IN2.

As described above, the first, second and third input terminals of the NAND circuit 151D receive “1”, “0” and “1”, respectively, the output of the NAND circuit 151D is “1”. That is, the value of the output terminal OUT1 is “1”, and the value of the input terminal IN1 is output from the output terminal OUT1 without being changed.

Further, when the value of the input terminal IN1 is “0”, the first, second and third input terminals of the NAND circuit 151D receive “1”, “1” and “1”, respectively. Hence, the output of the NAND circuit 151D is “0”. That is, the value of the output terminal OUT1 is “0”, and the value of the input terminal IN1 is output from the output terminal OUT1 without being changed.

As described above, the value of the output terminal OUT1 is set based on the delay increase signal (+) and the delay decrease signal (−) respectively input into the + terminal and the − terminal.

The value of the output terminal OUT1 is set to a value identical to the value of the adjacent input terminal IN0. Further, the value of the output terminal OUT1 is set to a value “0” identical to the value “0” of the adjacent input terminal IN2 when the value of the adjacent input terminal IN2 is “0” for decreasing the amount of delay. Moreover, the value of the input terminal IN1 is output from the output OUT1 as it is without being changed for maintaining the amount of delay.

Since the above-described operations are similar to those of the NAND circuits 152A to 152D, and the NAND circuits 153A to 153D, the descriptions of those of the NAND circuits 152A to 152D, and the NAND circuits 153A to 153D are omitted from the specification.

The delay setting data generator 150 of the signal delay device of the first embodiment sets 5 bit delay setting data in the shift register to adjust the amount of delay in the fine delay adjustment circuit 110A.

Next, description is given with reference to FIGS. 14A and 14B, of the detailed circuit configurations of the delay adjustment circuit 110A for fine adjustment and the selection signal generator 120, and the operations of the delay adjustment circuit 110, the selection signal generator 120, the shift register 130, and the change flag FF 170 of the signal delay device 100 of the first embodiment.

FIG. 14A is a diagram illustrating the delay adjustment circuit 110A for fine adjustment, the selection signal generator 120, the shift register 130, and the change flag FF 170 of the signal delay device 100 of the first embodiment.

FIG. 14B is a diagram illustrating a detailed circuit configuration of a part of the selection signal generator 120.

As already illustrated with reference to FIG. 10, the delay adjustment device 100 of the first embodiment includes the delay adjustment circuit 110A for fine adjustment and the delay adjustment circuit 110B for coarse adjustment. The circuit configurations of the delay adjustment circuits 110A and 110B are fundamentally the same except for the numbers of stages of the inverters and selectors.

Hence, description is given with reference to FIGS. 14A and 14B, of the detailed circuit configurations of the delay adjustment circuit 110A for fine adjustment and the selection signal generator 120, and the operations of the delay adjustment circuit 110A, the selection signal generator 120, the shift register 130, and the change flag FF 170.

As illustrated in FIG. 14A, the delay adjustment circuit 110A of the first embodiment is fundamentally similar to the delay adjustment circuit 10 of the comparative example of the signal delay device (see FIG. 1A). Hence, the delay adjustment circuit 110A of the first embodiment includes four stages of the forwarding-side inverters, four stages of the selectors, and four stages of the returning-side inverters.

Note that, the above-described numbers of stages of the forwarding-side inverters, the selectors and the returning-side inverters are only examples, and may be any numbers of stages. Similarly, the delay adjustment circuit 110B for coarse adjustment that is not illustrated in FIG. 14A may include any numbers of stages of the forwarding-side inverters, the selectors and the returning-side inverters.

The delay adjustment circuit 110A includes inverters 11, 12, 13 and 14, selectors 21, 22, 23 and 24, and inverters 31, 32, 33 and 34.

The inverters 11 to 14, selectors 21 to 24, and inverters 31 to 34 are configured to assign a delay to an input signal.

The connecting relationships of the inverters 11 to 14, the selectors 21 to 24, and the inverters 31 to 34, are similar to those of the inverters 11 to 14, the selectors 21 to 24, and the inverters 31 to 34 included in the comparative example of the delay adjustment circuit 10 illustrated in FIG. 1. Hence, the description of FIG. 1 is used for illustrating the connecting relationships in the delay adjustment circuit 110A of the first embodiment, and the duplicated description is omitted from the specification. Note that the selector 24 is supplied with the fixed data. As an example, the fixed data are assumed to be “0”.

Further, the selection signals supplied to the selectors 21 to 24 are generated by the selection signal generator 120.

The selection signal generator 120 is a logic circuit configured to generate selection signals to be supplied to the selectors 21 to 24 of the delay adjustment circuit 110A based on delay setting data held by the shift register 130.

The selection signal generator 120 includes selection signal generating logic circuits 121, 122, 123, and 124 for fine adjustment of the amount of delay. The selection signal generating logic circuits 121, 122, 123, and 124 are connected to the shift register 130 holding the delay setting data having a bit range obtained by adding one to the number of the selection signal generating logic circuits 121, 122, 123, and 124.

Note that the selection signal generator 120 further includes two selection signal generating logic circuits for coarse adjustment of the amount of delay in addition to those illustrated in FIG. 14A.

The selection signal generating logic circuits 121, 122, 123 and 124 have similar circuit configurations and each include a NAND circuit 201 and a selector 202. Circuit configurations of the selection signal generating logic circuits 121, 122, 123 and 124 will be described later.

The shift register 130 includes five delay setting flipflops (FFs) 1, 2, 3, 4 and 5 for fine adjustment of the amount of delay.

The shift register 130 holds one bit delay setting data in each of the delay setting FFs 1, 2, 3, 4 and 5. That is, the shift register 130 holds delay setting data having a bit range obtained by adding one to the number of the selectors 21 to 24 of the delay adjustment circuit 110A.

Note that the selection signal generator 130 further includes two selection signal generating logic circuits for coarse adjustment of the amount of delay in addition to those illustrated in FIG. 14A.

The change flag FF 170 outputs change flags to be input into the selection signal input terminals of the selectors 202 of the selection signal generating logic circuits 121 to 124. The change flag FF 170 is configured to set the change flags at the rise of the clock based on one of the delay increase signal (+) and the delay decrease signal (−).

Next, circuit configurations of the selection signal generating logic circuits 121, 122, 123 and 124 are described.

A first input terminal of the NAND circuit 201 of the selection signal generating logic circuit 121 is supplied with an output of the delay setting FF 1, and a second input terminal of the NAND circuit 201 of the selection signal generating logic circuit 121 is supplied with an inverted output of the delay setting FF 2.

A first input terminal of the selector 202 of the selection signal generating logic circuit 121 is supplied with an output (negative AND (NAND)) of the NAND circuit 201, and a second input terminal of the selector 202 of the selection signal generating logic circuit 121 is supplied with an output of the delay setting FF 2.

Further, a selection signal input terminal of the selector 202 of the selection signal generating logic circuit 121 is supplied with a change flag from the change flag FF 170. The selector 202 selects the output of the NAND circuit 201 to output the selected output of the NAND 201 when the value of the change flag input from the change flag FF 170 is “0”, whereas the selector 202 selects the delay setting data of the delay setting FF 2 to output the selected delay setting data of the delay setting FF 2 when the value of the change flag is “1”.

Further, the output of the selector 202 of the selection signal generating logic circuit 121 is supplied to the selector 21 of the delay adjustment circuit 110A as a selection signal 1.

A first input terminal of the NAND circuit 201 of the selection signal generating logic circuit 122 is supplied with an output of the delay setting FF 2, and a second input terminal of the NAND circuit 201 of the selection signal generating logic circuit 122 is supplied with an inverted output of the delay setting FF 3.

A first input terminal of the selector 202 of the selection signal generating logic circuit 122 is supplied with an output (negative AND (NAND)) of the NAND circuit 201, and a second input terminal of the selector 202 of the selection signal generating logic circuit 122 is supplied with an output of the delay setting FF 3.

Further, a selection signal input terminal of the selector 202 of the selection signal generating logic circuit 122 is supplied with a change flag from the change flag FF 170. The selector 202 selects the output of the NAND circuit 201 to output the selected output of the NAND 201 when the value of the change flag input from the change flag FF 170 is “0”, whereas the selector 202 selects the delay setting data of the delay setting FF 3 to output the selected delay setting data of the delay setting FF 3 when the value of the change flag is “1”.

Further, the output of the selector 202 of the selection signal generating logic circuit 122 is supplied to the selector 22 of the delay adjustment circuit 110A as a selection signal 2.

A first input terminal of the NAND circuit 201 of the selection signal generating logic circuit 123 is supplied with an output of the delay setting FF 3, and a second input terminal of the NAND circuit 201 of the selection signal generating logic circuit 123 is supplied with an inverted output of the delay setting FF 4.

A first input terminal of the selector 202 of the selection signal generating logic circuit 123 is supplied with an output (negative AND (NAND)) of the NAND circuit 201, and a second input terminal of the selector 202 of the selection signal generating logic circuit 123 is supplied with an output of the delay setting FF 4.

Further, a selection signal input terminal of the selector 202 of the selection signal generating logic circuit 123 is supplied with a change flag from the change flag FF 170. The selector 202 selects the output of the NAND circuit 201 to output the selected output of the NAND 201 when the value of the change flag input from the change flag FF 170 is “0”, whereas the selector 202 selects the delay setting data of the delay setting FF 4 to output the selected delay setting data of the delay setting FF 4 when the value of the change flag is “1”.

Further, the output of the selector 202 of the selection signal generating logic circuit 123 is supplied to the selector 23 of the delay adjustment circuit 110A as a selection signal 3.

A first input terminal of the NAND circuit 201 of the selection signal generating logic circuit 124 is supplied with an output of the delay setting FF 4, and a second input terminal of the NAND circuit 201 of the selection signal generating logic circuit 124 is supplied with an inverted output of the delay setting FF 5.

A first input terminal of the selector 202 of the selection signal generating logic circuit 124 is supplied with an output (negative AND (NAND)) of the NAND circuit 201, and a second input terminal of the selector 202 of the selection signal generating logic circuit 124 is supplied with an output of the delay setting FF 5.

Further, a selection signal input terminal of the selector 202 of the selection signal generating logic circuit 124 is supplied with a change flag from the change flag FF 170. The selector 202 selects the output of the NAND circuit 201 to output the selected output of the NAND 201 when the value of the change flag input from the change flag FF 170 is “0”, whereas the selector 202 selects the delay setting data of the delay setting FF 5 to output the selected delay setting data of the delay setting FF 5 when the value of the change flag is “1”.

Further, the output of the selector 202 of the selection signal generating logic circuit 124 is supplied to the selector 24 of the delay adjustment circuit 110A as a selection signal 4.

Note that the selection signal generating logic circuits 121 to 124 may be implemented by the logic circuit having a configuration illustrated in FIG. 14B. In the following, such an example is illustrated by using the selection signal generating logic circuit 121 as a representative example.

The selection signal generating logic circuit 121 includes AND circuits 211 and 212, and a NOR circuit 213.

A first input terminal of the AND circuit 211 of the selection signal generating logic circuit 121 is supplied with an output of the delay setting FF 1, and a second input terminal of the AND circuit 211 of the selection signal generating logic circuit 121 is supplied with an inverted output of the delay setting FF 2.

A first input terminal of the AND circuit 212 of the selection signal generating logic circuit 121 is supplied with an inverted output of the delay setting FF 2, and a second input terminal of the AND circuit 212 of the selection signal generating logic circuit 121 is supplied with a change flag from the change flag FF 170.

First and second input terminals of the NOR circuit 213 are supplied with the outputs (AND) of the AND circuits 211 and 212. The NOR circuit 213 outputs NOR of the outputs of the selection signal generating logic circuit 121 includes the AND circuits 211 and 212. The output of the NOR circuit 213 is equivalent to the output of the selector 202 of the selection signal generating logic circuit 121 illustrated in FIG. 14A. Hence, the output of the NOR circuit 213 is supplied to the selector 21 as a selection signal 1.

Note that selection signals 2 to 4 are supplied to the selectors 22 to 24 from the selectors 202 of the selection signal generating logic circuits 122 to 124, respectively, in a manner similar to the selection signal generating logic circuit 121 illustrated in FIG. 14A.

Next, a description will be given, with reference to FIGS. 15A and 15B, of the delay setting data held by the shift register 130.

FIG. 15A is a diagram illustrating an example of a corresponding relationship between the delay setting data and the delay number (delay No.) held by the shift register 130 of the signal delay device 100 of the first embodiment. The delay number corresponds to a delay time of the signal delay device 100. FIG. 15B is a diagram illustrating the delay setting data held by the shift register 130 of the signal delay device 100 of the first embodiment together with the change flag and a selection signal.

As illustrated in FIG. 15A, the delay setting data include 5 bit data set in the delay setting FFs 1 to 5 for fine adjustment, and 3 bit data set in the three delay setting FFs for coarse adjustment.

The 5 bit delay setting data for fine adjustment set in the delay setting FFs 1 to 5 are supplied to the selection signal generating logic circuits 121 to 124 (see FIG. 14A) for fine adjustment inside the selection signal generator 120. Likewise, the 3 bit delay setting data for coarse adjustment set in the three delay setting FFs are supplied to the two selection signal generating logic circuits for coarse adjustment inside the selection signal generator 120.

As illustrated in FIG. 15A, the delay setting data for coarse adjustment and the delay setting data for fine adjustment are configured such that the leftmost data are “1” and the rightmost data are “0”. Further, the delay setting data for coarse adjustment and the delay setting data for fine adjustment are configured such that the boundary of “1” and “0” is shifted to the right, as the delay number (delay No.) is incremented with respect to the identical delay setting data for coarse adjustment.

As illustrated in FIG. 15A, the 3 bit delay setting data for coarse adjustment are fixed to “1”, “0”, and “0” while the delay number is 0 to 3. Further, the 5 bit delay setting data set in the delay setting FFs 1 to 5 for fine adjustment start with “1”, “0”, “0”, “0” and “0”, and the delay setting data set in the delay setting FFs 1 to 4 are sequentially set to “1”. When the delay number (delay No.) is 3, the 5 bit delay setting data for fine adjustment are “1”, “1”, “1”, “1” and “0”.

When the delay number (delay No.) is 4, the 3 bit delay setting data for coarse adjustment are “1”, “1” and “0”, and the 5 bit delay setting data for fine adjustment are returned to “1”, “0”, “0”, “0” and “0”.

The 3 bit delay setting data for coarse adjustment are fixed to “1”, “1” and “0” while the delay number (delay No.) is from 4 to 7, and the delay setting data set in the delay setting FFs 1 to 4 are sequentially set to “1” as the 5 bit delay setting data for fine adjustment. When the delay number (delay No.) is “7, the 5 bit delay setting data for fine adjustment are “1”, “1”, “1”, “1” and “0”.

Note that since the delay setting data are input from the two delay setting FFs to each of the selection signal generating logic circuits 121 to 124 for fine adjustment illustrated in FIG. 14A, the input into the left-hand side input terminal is called a left input and the input into the right-hand side input terminal is called a right input for convenience of illustration.

When the change flag is OFF (“0”), the outputs of the NAND circuits 201 of the selection signal generating logic circuits 121 to 124 are input into the selectors 21 to 24 as the selection signals 1 to 4, respectively.

As described above, the delay setting data are configured such that the left-hand side data are “1” and the right-hand side data are “0”.

Note that the output (i.e., selection signal) of any one of the selection signal generating logic circuits 121 to 124 having respective values of the left input and the right input being “1” and “1” is “1”, and the delay setting data includes the left-hand side data being “1”, as described above. The delay setting data are configured such that the left-hand side data are “1” and the right-hand side data are “1”.

Hence, a combination of the delay setting data having the left input and the right input being “1” and “1” serves as a combination of delay setting data for generating a selection signal to be input into the selector that transfers a signal input from any one of the inverters 32 to 34 of the former stage (the right hand-side in FIG. 14A) to any one of the inverters 31 to 33 (the left hand-side in FIG. 14A) of the subsequent stage.

Further, a combination of the delay setting data having the left input and the right input being “1” and “0” serves as a boundary between data “1” and data “0” of the delay setting data.

When the left input and the right input are “1” and “0”, respectively, the output (selection signal) of any one of the selection signal generating logic circuits 121 to 124 is “0”. Hence, the selector corresponding to the selection signal generating logic circuit having the left input and the right input being “1” and “0” serves as a signal turning point.

Further, when the left input and the right input are “0” and “0”, respectively, the output (i.e., selection signal) of any one of the selection signal generating logic circuits 121 to 124 is “1”, and hence, the delay setting data have the right-hand side data being “0” as described above.

Hence, a combination of the delay setting data having the left input and the right input being “0” and “0” is used for generating a selection signal to be input into a selector that is situated at a position away from the selector serving as a signal turning point as viewed from the input terminal IN and the output terminal OUT and is set to the power-saving mode.

As described above, the selection signal generator 120 illustrated in FIG. 14A detects a boundary of the consecutive 0 data or 1 data included in the delay setting data when the change flag is “0”, and outputs a selection signal generated based on the 0 data or 1 data defining the boundary position to any one of the selectors 21 to 24 corresponding to the amount of delay of the delay signal. The boundary of the consecutive 0 data or 1 data corresponds to a part at which the left input and the right input are “1” and “0”, respectively, in the combination of the delay setting data.

The combination of the delay setting data having the left input and the right input being “1” and “0”, respectively, is a combination of the delay setting data for generating the selection signal of any one of the selectors 21 to 24 that serves as a signal turning point.

Further, when the change flag is “0”, the selection signal generator 120 illustrated in FIG. 14A outputs a selection signal generated based on AND of the 0 data and 1 data specifying the boundary position to the any one of the selectors 22 to 24 configured to select a selection signal output from any one of the inverters 12 to 14 corresponding to an amount of delay greater than the amount of delay of the delay signal.

That is, any one of the selectors 22 to 24 situated at a position away from the selector serving as a signal turning point as viewed from the input terminal IN and the output terminal OUT is supplied with the selection signal generated based on the combination of the delay setting data having the left input and the right input being “0” and “0”.

As described above, in the signal delay device 100 of the first embodiment, the amount of delay in the delay adjustment circuit 110 may be controlled by causing the shift register 130 to sequentially shift the delay setting data illustrated in FIG. 15A.

Note that the above-described control of the amount of delay in the delay adjustment circuit 110 may also be performed in the selection signal generating logic circuits for coarse adjustment included in the selection signal generator 120.

Hence, when the delay number (delay No.) is “0”, the selector 21 serves as a signal turning point within the delay adjustment circuit 110A for fine adjustment, and similarly, one of the two selectors that is situated at a position closer to the input terminal IN and the output terminal OUT serves as a signal turning point within the delay adjustment circuit 110B for fine adjustment. Hence, the delay time when the delay number (delay No.) is “0” is 100 ps obtained by adding the delay time 80 ps for coarse adjustment to the delay time 20 ps for fine adjustment.

When the delay number (delay No.) is “7”, the selector 24 serves as a signal turning point within the delay adjustment circuit 110A for fine adjustment, and similarly, one of the two selectors that is situated at a position away from the input terminal IN and the output terminal OUT serves as a signal turning point within the delay adjustment circuit 110B for fine adjustment. Hence, the delay time when the delay number (delay No.) is “7” is 240 ps obtained by adding the delay time 160 ps for coarse adjustment to the delay time 80 ps for fine adjustment.

Hence, the amount of delay may be adjusted in a range of 100 to 240 ps by shifting the delay setting data for fine adjustment and the delay setting data for coarse adjustment.

Note that the delay setting data include the value of “0” or “1”. However, the delay setting data may include an inverted value of “0” or “1”, which may be implemented by adding a NOT operator configured to perform NOT computation in the selection signal generator 120 or the shift register 130.

Next, a description is given, with reference to FIG. 15B, of a combination and operations of the delay setting data, the change flag, and the selection signal.

In the first embodiment, the delay setting data are the 5 bit delay setting data set in the delay setting FFs 1 to 5, which are supplied to the selection signal generating logic circuits 121 to 124, respectively.

The selection signal generating circuit 121 is supplied with the respective delay setting data from the delay setting FF 1 on the left-hand side and the delay setting FF 2 on the right-hand side. In FIG. 15B, the respective delay setting data held by the delay setting FFs 1 and 2 are expressed by the left input and the right input.

Likewise, the respective delay setting data held by the delay setting FFs 2 and 3 supplied to the selection signal generating logic circuit 122 are expressed by the left input and the right input. Further, the respective delay setting data held by the delay setting FFs 3 and 4 supplied to the selection signal generating logic circuit 123 are expressed by the left input and the right input, and the respective delay setting data held by the delay setting FFs 4 and 5 supplied to the selection signal generating logic circuit 124 are expressed by the left input and the right input.

In addition, the selection signal generating logic circuits 121 to 124 perform identical operations with respect to the change flag, the left input, and the right input. Hence, in FIG. 15B, the NAND circuits 201 and the selectors 202 included in the selection signal generating logic circuits 121 to 124 are not separately illustrated, and therefore, the selection signals 1 to 4 are not separately described but integrally illustrated as a selection signal.

Initially, a case where the change flag is “0”, the left input is “0”, and the right input is “0” is described.

When the left input and the right input are “0” and “0”, respectively, the output of the NAND 201 is “1”. Further, when the change flag is “0”, the selector 202 selects the output of the NAND circuit 201. Hence, the selection signal output from the selector 202 is “1”.

Note that the selector corresponding to the selection signal generating logic circuit having respective values of the left input and the right input being “1” and “0” serves as a signal turning point.

Hence, when the change flag is “0”, the delay setting data having the left input and the right input being “0” and “0” are a combination of the delay setting data with respect to any one of the selection signal generating logic circuits 122 to 124 that inputs a selection signal to any one of the selectors 22 to 24 that is situated at a position away from the input terminal IN and the output terminal OUT of the delay adjustment circuit 110 in relation to the selector serving as a signal turning point.

Note that since the selection signal is set to “1”, any one of the selectors 22 to 24 within the delay adjustment circuit 110A for fine adjustment is set to the power-saving mode.

Next, a case where the change flag is “0”, the left input is “1”, and the right input is “0” is described.

When the left input and the right input are “1” and “0”, respectively, the output of the NAND 201 is “0”. When the change flag is “0”, the selector 202 selects the output of the NAND circuit 201. Hence, the selection signal output from the selector 202 is “0”. Further, the selection signal having a value of “0” is a selection signal to be into any one of the selectors 21 to 24 that serves as a signal turning point.

Hence, when the change flag is “0”, the delay setting data having the left input and the right input being “1” and “0” are a combination of the delay setting data with respect to any one of the selection signal generating logic circuits 121 to 124 that inputs a selection signal to any one of the selectors 21 to 24 that serves as a signal turning point in the delay adjustment circuit 110.

Next, a case where the change flag is “0”, the left input is “1”, and the right input is “1” is described.

When the left input and the right input are “1” and “1”, respectively, the output of the NAND 201 is “1”. When the change flag is “0”, the selector 202 selects the output of the NAND circuit 201. Hence, the selection signal output from the selector 202 is “1”.

Hence, when the change flag is “0”, the delay setting data having the left input and the right input being “1” and “1” are a combination of the delay setting data with respect to any one of the selection signal generating logic circuits 121 to 123 that inputs a selection signal to any one of the selectors 21 to 23 that is situated at a position close to the selector serving as a signal turning point as viewed from the input terminal IN and the output terminal OUT of the delay adjustment circuit 110.

Next, a case when the change flag is “0” is described. When the change flag is OFF (“1”), each of the selectors 202 within the selection signal generating logic circuits 121 to 124 outputs the right input as it is. Hence, the left inputs are not involved. Hence, in FIG. 15B, the left input when the change flag is “1” is illustrated as “X”.

Initially, a case where the change flag is “1”, and the right input is “0” is described.

When the change flag is “1”, and the right input is “0”, the selection signal output from the selector 202 is “0”.

Note that as illustrated in FIG. 15A, a case where the right input is “0” is involved in any one of the selection signal generating logic circuits 122 to 124 that inputs a selection signal into any one of the selectors 21 to 24 that serves as a signal turning point, or any one of the selectors 21 to 24 that is situated away from the input terminal IN and the output terminal OUT in relation to the signal turning point.

Further, the change flag is “1” when the selector serving as a signal turning point is changed.

Hence, a case where the right input is “0” when the change flag is “1” is involved in any one of the selection signal generating logic circuits 122 to 124 that inputs a selection signal into any one of the selectors 21 to 24 that serves as a new signal turning point, or any one of the selectors 21 to 24 that is situated away from the input terminal IN and the output terminal OUT in relation to a signal turning point.

Note that all the selectors 22 to 24, 23 to 24, or 24 situated at a position away from any one of the selectors 21 to 24 serving as a new signal turning point as viewed from the input terminal IN and the output terminal OUT are supplied with a signal from any one of the forwarding-side inverters 11 to 14 when the selection signal is “0”. That is the power-saving mode is OFF.

Hence, all the selectors 22 to 24, 23 to 24, or 24 situated at the position away from any one of the selectors 21 to 24 serving as the new signal turning point as viewed from the input terminal IN and the output terminal OUT turn the power-saving mode OFF when the signal turning point is switched.

Hence, when the signal turning point is switched, the power-saving modes of all the selectors 22 to 24, 23 to 24, or 24 situated at the position away from the input terminal IN and the output terminal OUT are tuned OFF by resetting the selection signals input into the above selectors to

Next, a case where the change flag is “1”, and the right input is “1” is described.

When the change flag is “1”, and the right input is “1”, the selection signal is “1”. Further, the change flag is “1” when the signal turning point is changed.

Hence, a case where the right input is “1” when the change flag is “1” is involved in any one of the selection signal generating logic circuits 121 to 123 that inputs a selection signal into any one of the selectors 21 to 2 that serves as a new signal turning point when the signal turning point is changed.

As described above, in the signal delay device 100 of the first embodiment, the selection signals 1 to 4 are set and the power-saving mode is switched by utilizing the delay setting data and the change flags illustrated in FIG. 15B.

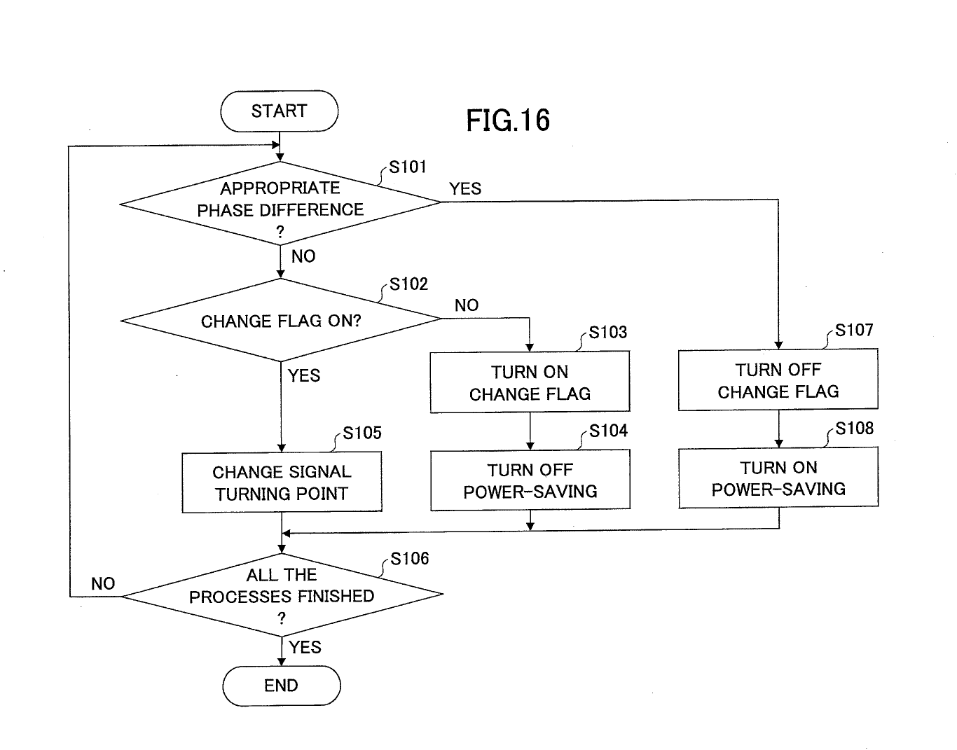

Next, a description will be given, with reference to FIG. 16, of delaying processing in the signal delay device 100 of the first embodiment. The delay process illustrated in FIG. 16 implemented by the signal delay device 100 illustrated in FIG. 10 that represents a control method of the signal delay device 100.

FIG. 16 is a flowchart illustrating the delay process in the signal delay device 100 of the first embodiment.

The signal delay device 100 determines whether a phase difference between the data signal D and the capturing signal C is appropriate when the change flag is OFF (i.e., the power-saving mechanism is ON) (step S101).

Whether the phase difference between the data signal D and the capturing signal C is appropriate is determined by the delay adjustment judgment part 140 (see FIG. 11). The delay adjustment judgment part 140 determines whether the rise of the capturing signal C falls within a predetermined range before and after the center of a half cycle of the data signal D.

When the delay adjustment determining part 140 determines that the phase difference between the data signal D and the capturing signal C is appropriate (“YES” in Step S101), the signal delay device 100 determines whether the change flag is ON (step S102). Whether the change flag is ON is determined based on the value of the change flag output from the change flag FF 170 or the value of the change flag input into the selection signal generator 120.

When the signal delay device 100 determines that the change flag is not ON in step S102 (“NO” in step S102), a process in step S103 is processed, in which the change flag is ON at the rise of the clock signal (step S103). In this step, since the phase difference is already determined as inappropriate in step S101, and the change flag is determined as being OFF in step S102, the change flag is turned ON for preparing for changing the signal turning point.

Subsequently, the signal delay device 100 turns the power-saving mechanism OFF (step S104). The signal delay device 100 turns the power-saving mechanism OFF when the change flag is ON.

The signal delay device 100 determines whether all the processes have been finished when the process in step S104 is finished (step S106). To finish all the processes indicates to finish operations of the signal delay device 100.

The signal delay device 100 determines that all the processes have not been finished (“NO” in step S106), and the process in step S101 is processed (back to step S101).

The signal delay device 100 determines whether the phase difference is appropriate in step S101 again. However, since the signal turning point is yet to be changed after the signal delay device 100 determines that the phase difference is not appropriate in step S101 in a previous cycle, the signal delay device 100 determines that the phase difference is not appropriate (step S101). Thus, a process in step S102 is subsequently processed.

The signal delay device 100 determines whether the change flag is ON in step S102 in the second cycle (step S102). Since the change flag is ON in step S103 in the first cycle, the signal delay device 100 determines that the change flag is ON in step S102 in the second cycle in step S102 (“YES” in step S102). As a result, a process in step S105 is subsequently processed.

The signal delay device 100 executes the change of the signal turning point (step S105). Hence, the selection signals 1 to 4 are switched from “0”, “1”, “1”, and “1”, to “1”, “0”, “1”, and “1”, and the signal turning point is changed from the selector 21 to the selector 22.

Note that as described above, the signal delay device 100 includes an interval of one clock cycle from a time where the change flag is turned ON in step S103 in the first cycle to a time where the signal turning point is changed in step S105 in the second cycle.

The invalid data generated due to the power-saving mechanism within the delay adjustment circuit 110 are eliminated during one clock cycle. Hence, the data signal may be accurately captured by utilizing the capturing signal C obtained after the signal turning point has been changed.

The signal delay device 100 determines whether all the processes have been finished when the process in step S105 is finished (step S106). To finish all the processes indicates to finish operations of the signal delay device 100.

The signal delay device 100 determines that all the processes have not been finished (“NO” in step S106), the process in step S101 is processed (back to step S101).

The signal delay device 100 determines whether the phase difference is appropriate in step S101 in the third cycle (step S101).

When the phase difference is appropriate (“YES” in step S101), the signal delay device 100 proceeds with a process in step S107. On the other hand, when the phase difference is not appropriate (“NO” in step S101), the signal delay device 100 proceeds with processes in steps S102 and S105, and repeatedly proceeds with the processes in steps in S101, S102, S105 and S106.

When the phase difference is determined as appropriate (“YES” in step S101), the signal delay device 100 turns the change flag OFF (step S107). Since the value of the amount of delay of the capturing signal C is appropriate and the change of the signal turning point is unnecessary, the signal delay device 100 turns the change flag OFF.

Subsequently, the signal delay device 100 turns the power-saving mechanism ON (step S108). When the change of the signal turning point is finished, the power-saving mechanism is turned ON again in order to suppress the electric power consumption.

As described above, the delay process in the signal delay device 100 of the first embodiment illustrated in FIG. 16 is finished.

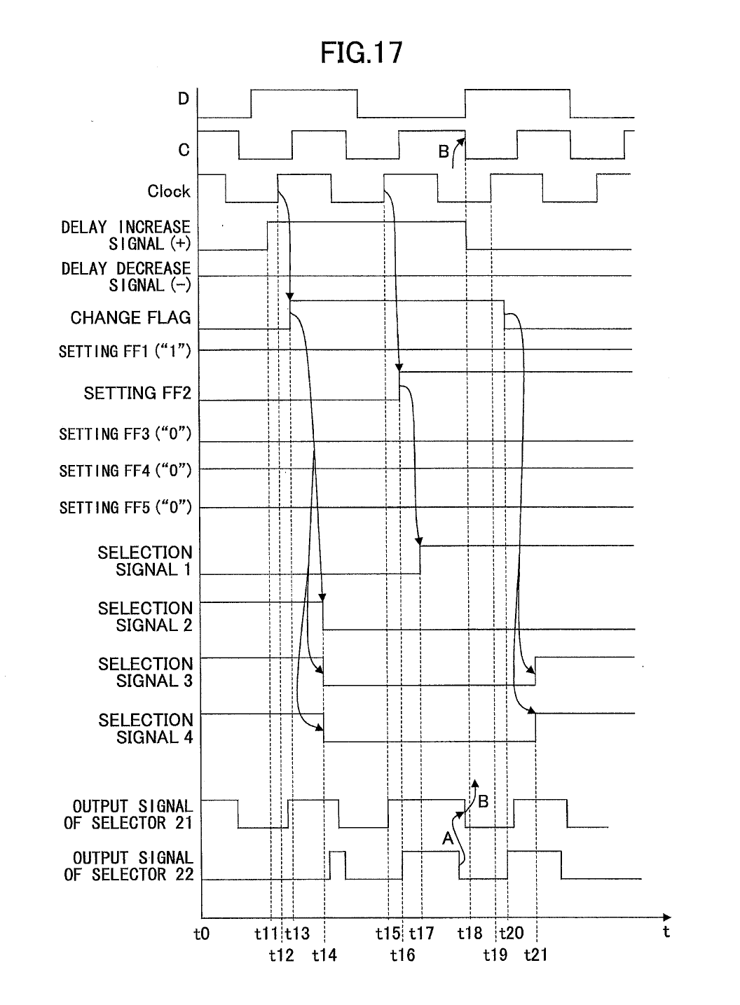

Next, a description will be given, with reference to FIG. 17, of operations of the signal delay device 100 of the first embodiment.

FIG. 17 is a diagram illustrating a timing chart indicating a relationship between the delay setting data and the selection signals in the delay adjustment circuit 110A for fine adjustment of the signal delay device 100 of the first embodiment.

In the following, a description is given of a case where the delay setting data illustrated in FIG. 15A are shifted from the delay number 0 (delay No. 0) to the delay number 1 (delay No. 1). That is, a description is given of a case where the signal turning point in the delay adjustment circuit 110B for coarse adjustment within the signal delay device 100 is fixed, and the signal turning point within the delay adjustment circuit 110A for fine adjustment is changed from the selector 21 to the selector 22.

As illustrated in FIG. 17, since the signal turning point of the signal delay device 100 is the selector 21, and the power-saving mechanism is ON at time t0, the selection signal 1 is “0”, and each of the selection signals 2 to 4 is “1”.

At time t11, when the phase difference between the data signal D and the capturing signal C being greater than a predetermined threshold is detected, the delay increase signal (+) rises to “1”. Note that the delay decrease signal (−) remains unchanged as “0”.

Note that the predetermined threshold may, for example, be set to the value representing the phase difference between the data signal D and the capturing signal C when the rise of the capturing signal C resides within a predetermined range before and after the center of the half cycle of the data signal D.

When the delay increase signal (+) rises to “1”, preparation for changing the signal turning point at the rise of the clock at time t12 is initiated and the change flag is turned ON at time t13. Hence, the power-saving mode is turned OFF, and the selection signals 2 to 4 are switched from “1” to “0” at time t14.

When the selection signals 2 to 4 are switched from “1” to “0” in a state where the power-saving mechanism is OFF, data input from the input terminal IN of the delay adjustment circuit 110 are reflected in the inverters 32, 33 and 34 via the inverters 12, 13 and 14, and then via the selectors 22, 23 and 24, respectively.

Note that since the signal turning point is selector 21 and the power-saving mechanism is ON before time t14, the invalid data are present in an interval between the output terminal of the selector 24 and the output terminal of the inverter 32.

However, when the change flag is ON at time t13, the power-saving mechanism is turned OFF at time t14. Hence, the data input from the input terminal are reflected in the inverters 32, 33 and 34 via the selectors 22, 23 and 24, respectively, which thereby eliminates the invalid data present in the interval between the output terminal of the selector 24 and the output terminal of the inverter 32.

Subsequently, when the clock rises at time t15, the delay setting FF 2 of the shift register 130 is switched to “1” at time t16 to change the signal turning point. That is, the delay setting data illustrated in FIG. 15A are shifted from the delay number 0 (delay No. 0) to the delay number 1 (delay No. 1).

Then, when the delay setting FF 2 is switched to “1”, the selection signal 1 is switched to “1” at time t17.

At this moment, since the delay setting FF 3 remains unchanged as “0”, and the change flag is ON, the value “0” of the delay setting FF 3 is the value “0” of the selection signal 2. As a result, the selector 22 serves as the signal turning point.

When the signal turning point is switched to the selector 22 at time t17, the output signal of the selector 22 is propagated to the selector 21 via the inverter 32. Hence, the fall of the output signal of the selector 22 is propagated as the fall of the output signal of the selector 21 as indicated by an arrow A in FIG. 17.

Hence, the fall of the output signal of the selector 21 after time t17 is delayed.

Then, the delayed output signal of the selector 21 delays the capturing signal C output from the output terminal OUT of the delay adjustment circuit 110 as indicated by an arrow B.

Hence, the rise of the capturing signal C is thereafter situated at the center of the half cycle of the data signal D.

Note that when the phase difference between the data signal D and the capturing signal C is less than or equal to the predetermined threshold at time t18, the delay increase signal (+) falls. That is, the phase difference between the data signal D and the capturing signal C is determined as being greater than a predetermined threshold in an interval between time 11 and time t18, where the delay increase signal (+) is at H level.

When the phase difference between the data signal D and the capturing signal C is determined as being appropriate at the rise of the clock at time t19, the change flag is turned OFF at time t20.

Hence, when the change flag is OFF, the power-saving mechanism is ON. Hence, the selection signals 3 and 4 are switched to “1” at time t21 to input fixed data to the selectors 23 and 24 situated away from the input terminal IN and the output terminal OUT of the delay adjustment circuit 110 in relation to the selector 22 serving as a signal turning point.

At this moment, according to the delay number 1 (delay No. 1), the delay setting FF 2 is “1”, and the delay setting FF 3 is “0”.

The value “0” of the delay setting FF 3 is supplied as the selection signal 2 to the selector 22 while the change flag is ON. However, after the change flag is ON, the value “0” of the selection signal 2, which the NAND 201 within the selection signal generating logic circuit 122 outputs based on the value “1” of the delay setting FF 2 and the value “0” of the delay setting FF 3, is input into the selector 22.

Hence, the signal turning point remain unchanged as the selector 22 before and after switching ON/OFF of the change flag.

As described above, the signal delay device 100 of the first embodiment turns the power-saving mechanism OFF when the phase difference between the data signal D and the capturing signal C is greater than or equal to a predetermined threshold, and changes the signal turning point after one clock cycle time has elapsed.

Hence, the invalid data may be eliminated while awaiting the one clock cycle period (preparation period), and the accurate data signal D may be captured without capturing the invalid data by capturing the data signal D using the delay adjusted capturing signal C.

Further, since the signal delay device 100 of the first embodiment may be able to capture the accurate data signal D as described above, the server 90 (see FIG. 9) including the signal delay device 100 of the first embodiment in the I/O port 99 may be able to suppress degraded operations due to capturing of the invalid data and exhibit improved operating stability and reliability.

So far, the signal delay device 100 including the delay adjustment circuit 110A for fine adjustment is described. However, when the signal delay device 100 further includes the delay adjustment circuit 110B for coarse adjustment, the signal may drastically be changed by adjusting the amount of delay in a smaller extent. Hence, when the signal delay device 100 includes the delay adjustment circuit 110B for coarse adjustment that is controlled in a manner similar to the delay adjustment circuit 110A for fine adjustment, the signal delay device 100 having an increased adjustable range of the amount of delay and improved operating stability and reliability may be provided.

Further, as described above, the signal delay device 100 of the first embodiment switches ON the power-saving mechanism again when the signal turning point has been changed. Hence, the signal delay device 100 may be able to save the electric power.

Hence, the server 90 may be able to save electric power by using the signal delay device 100 of the first embodiment in the I/O port 99 (see FIG. 9).

As described above, the first embodiment may be able to provide the signal delay device capable of reducing the electric power consumption and exhibiting the accuracy of the output signals, and the control method of such a signal delay device.

### Second Embodiment

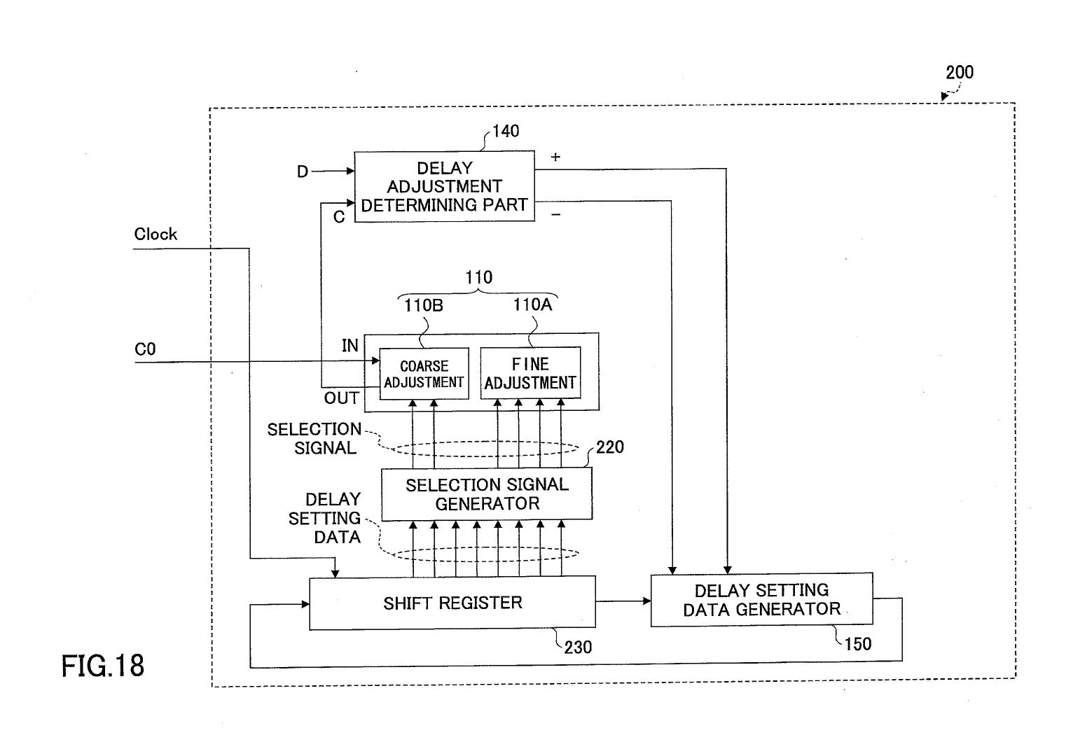

FIG. 18 is a diagram illustrating a signal delay device 100 of a second embodiment.

The signal delay device 100 of the second embodiment includes a delay adjustment circuit 110A, a selection signal generator 220, a shift register 230, a delay adjustment judgment part 140, and a delay setting data generator 150.

The signal delay device 200 of the second embodiment differs from the signal delay device 100 of the first embodiment in that the signal delay device 200 of the second embodiment does not include the OR circuit 160, the change flag FF 170, and the AND circuit 180 (see FIG. 10).

In the following, the elements of the signal delay circuit 200 of the second embodiment that are the same as or equivalent to those of the delay circuit 100 of the first embodiment are designated by the same reference numerals, and their descriptions will therefore be omitted from the specification of the present application.

The selection signal generator 220 is configured to generate a selection signal to be supplied to the fine delay adjustment circuit 110A based on delay setting data held by the shift register 230. The selection signal generator 220 of the second embodiment is not supplied with the value of the change flag as the selection signal generator 120 of the first embodiment. Hence, the selection signal generator 220 of the second embodiment differs from the selection signal generator 120 of the first embodiment in that the selection signal generator 220 operates based on the delay setting data input from the shift register 230 alone.

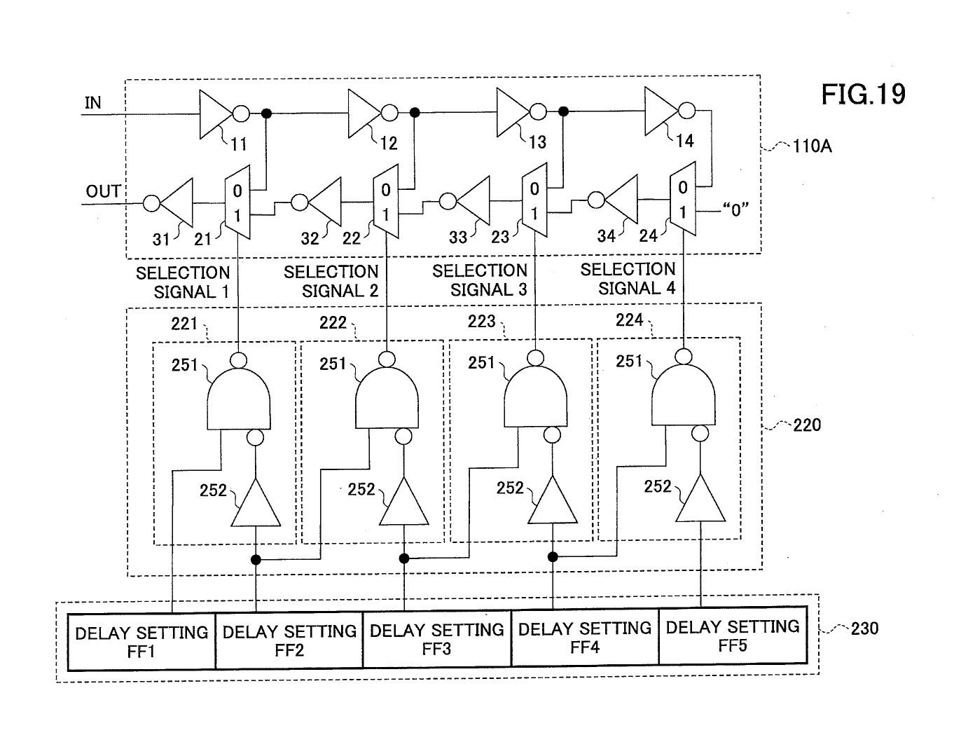

Note that a circuit configuration of the selection signal generator 220 will be described later with reference to FIG. 19.

The shift register 230 is configured to hold delay setting data set by the delay setting data generator 150. The shift register 230 differs from the shift register 130 in that the shift register 230 is directly supplied with the clock, and the delay setting data are updated at the rise of the clock.

Next, a description will be given, with reference to FIG. 19, of circuit configurations and operations of the fine delay adjustment circuit 110A, the selection signal generator 220, and the shift register 230 of the signal delay device 200 of the second embodiment.

FIG. 19 is a diagram illustrating circuit configurations of the fine delay adjustment circuit 110A, the selection signal generator 220, and the shift register 230 of the signal delay device 200 of the second embodiment.

The selection signal generator 220 includes selection signal generating logic circuits 221, 222, 223, and 224. The selection signal generating logic circuits 221, 222, 223, and 224 are connected to the shift register 230 holding the delay setting data having a bit range obtained by adding one to the number of the selection signal generating logic circuits 221, 222, 223, and 224.

The selection signal generating logic circuits 221, 222, 223 and 224 have similar circuit configurations and each include a NAND circuit 251 and a buffer 252. The buffer 252 is an example of the delay circuit configured to assign a delay to an input signal and output the delayed input signal. The buffer 252 may be an element having a delay time of the input or output corresponding to approximately one clock cycle.

The shift register 230 includes five delay setting flipflops (FFs) 1, 2, 3, 4 and 5.

A first input terminal of the NAND circuit 251 of the selection signal generating logic circuit 221 is supplied with an output of the delay setting FF 1, and a second input terminal of the NAND circuit 221 of the selection signal generating logic circuit 221 is supplied with an inverted output of the delay setting FF 2 via the buffer 252. The output signal of the NAND circuit 251 of the selection signal generating logic circuit 221 is supplied to a selection signal input terminal of the selector 21 of the fine delay adjustment circuit 110A as a selection signal 1.

A first input terminal of the NAND circuit 251 of the selection signal generating logic circuit 222 is supplied with an output of the delay setting FF 2, and a second input terminal of the NAND circuit 251 of the selection signal generating logic circuit 222 is supplied with an inverted output of the delay setting FF 3 via the buffer 252. The output signal of the NAND circuit 251 of the selection signal generating logic circuit 222 is supplied to a selection signal input terminal of the selector 22 of the fine delay adjustment circuit 110A as a selection signal 2.

A first input terminal of the NAND circuit 251 of the selection signal generating logic circuit 223 is supplied with an output of the delay setting FF 3, and a second input terminal of the NAND circuit 251 of the selection signal generating logic circuit 223 is supplied with an inverted output of the delay setting FF 4 via the buffer 252. The output signal of the NAND circuit 251 of the selection signal generating logic circuit 223 is supplied to a selection signal input terminal of the selector 23 of the fine delay adjustment circuit 110A as a selection signal 3.

A first input terminal of the NAND circuit 251 of the selection signal generating logic circuit 224 is supplied with an output of the delay setting FF 4, and a second input terminal of the NAND circuit 251 of the selection signal generating logic circuit 224 is supplied with an inverted output of the delay setting FF 5 via the buffer 252. The output signal of the NAND circuit 251 of the selection signal generating logic circuit 224 is supplied to a selection signal input terminal of the selector 24 of the fine delay adjustment circuit 110A as a selection signal 4.

The selection signal generating logic circuit 221 of the signal delay device 200 of the second embodiment is supplied with the delay setting data “0” and “0” from the delay setting FFs 1 and 2, respectively, and the delay setting data “0” of the delay setting FF 2 is input into the NAND circuit 251 via the buffer 252. At this moment, the selection signal 1 output by the NAND circuit 251 is 1.

When the delay setting data of the delay setting FFs 1 and 2 are changed from “0” and “0” to “1” and “1”, the right input of the NAND 251 is delayed by the buffer 252. Hence, the delay setting data “1” and “0” are temporarily input into the NAND circuit 251. Thus, at this middle stage, the selection signal 1 output by the NAND circuit 251 becomes “0”. The signal delay device 200 of the second embodiment uses this middle stage generated by the delay time of the buffer 252 as a preparation period for clearing the invalid data.

Then, when the delay time of the input and output of the buffer 252 has elapsed and the delay setting data “1” and “1” are input into the NAND circuit 251, the selection signal 1 of the NAND circuit 251 becomes “1”.

The signal delay device 200 of the second embodiment implements operations similar to those of the signal delay device 100 of the first embodiment having the preparation period corresponding to one clock cycle when the signal turning point is switched by using the buffer 252 as an example of the preparation period setting part as described above.

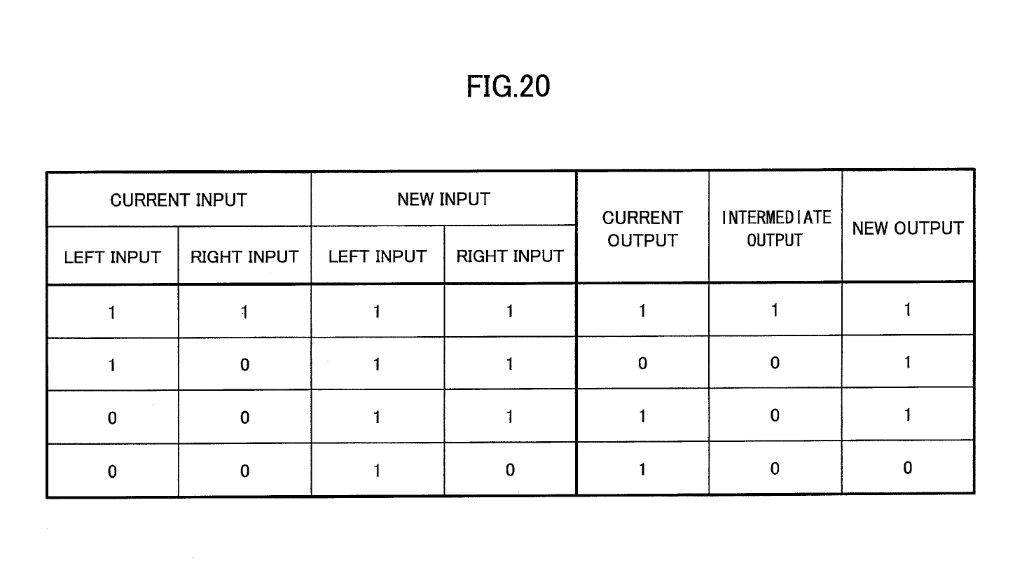

Next, a description will be given, with reference to FIG. 20, of combinations of the delay setting data for acquiring the selection signals 1 to 4 in the signal delay device 200 of the second embodiment.

FIG. 20 is a table illustrating the combinations of the delay setting data for acquiring the selection signals 1 to 4, and output signals of a NAND circuit 251 to be output as the selection signals 1 to 4.

Note that the delay setting data are illustrated as a combination of 2 bit data input into each of the selection signal generating logic circuits 221 to 224. Each of the inputs to the left-hand side input terminals of the selection signal generating logic circuits 221 to 224 is called a “left input”, and each of the inputs to the right-hand side input terminals of the selection signal generating logic circuits 221 to 224 is called a “right input”.

Further, the delay setting data before being changed are called a “current input”, and new delay setting data after being changed are called a “new input”. The current input and the new input are indicated by the left input and the right input, respectively.

Of the selection signals output from the NAND circuit 251, the output reflecting the current input is called a “current output”. The output reflecting the new input in the left-hand side input terminal of the NAND circuit 251 alone is called an “intermediate output”. Further, the output further reflecting the new input in the right-hand side input terminal of the NAND circuit 251 is called a “new output”.

When the left input and the right input are “1” and “1”, respectively, the current output is “1”. When “1” and “1” are input as the new left input and right input, the intermediate output is 1, and the new output is “1”. In this combination pattern, the selection signals serving as the outputs are “1”.

When the left input and the right input are “1” and “0”, respectively, the current output is “0”. When “1” and “1” are input as the new left input and right input, the intermediate output is 0, and the new output is “1”. In this combination pattern, the selection signals serving as the outputs are “0”, “0”, and “1” in the order of the current output, the intermediate output, and the new output.

When the left input and the right input are “0” and “0”, respectively, the current output is “1”. When “1” and “1” are input as the new left input and right input, the intermediate output is 0, and the new output is “1”. In this combination pattern, the selection signals serving as the outputs are changed as being “1”, “0”, and “1” in the order of the current output, the intermediate output, and the new output.

When the left input and the right input are “0” and “0”, respectively, the current output is “1”. When “1” and “0” are input as the new left input and right input, the intermediate output is 0, and the new output is “0”. In this combination pattern, the selection signals serving as the outputs are changed as being “1”, “0”, and “0” in the order of the current output, the intermediate output, and the new output.

The signal delay device 200 of the second embodiment may be drive controlled by inputting the 5-bit delay setting data represented by the combinations of the left input and the right input illustrated in FIG. 20 into the respective selection signal generating logic circuits 221 to 224

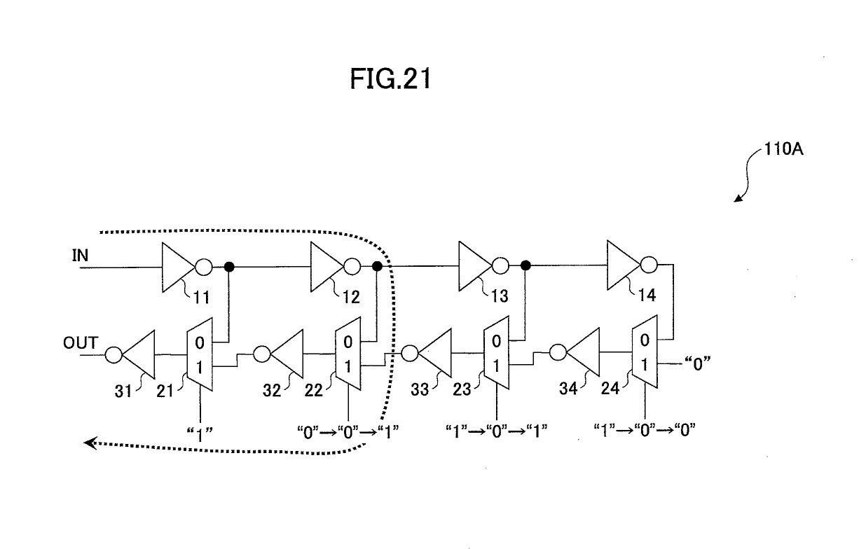

Next, a description will be given, with reference to FIG. 21, of switching of the signal turning point in the fine delay adjustment circuit 110A.

FIG. 21 is a schematic diagram illustrating switching of a signal turning point of the fine delay adjustment circuit 110A of the signal delay device 200 of the second embodiment.

Assume that delay setting data “1”, “1”, “0”, “0” and “0 are supplied as new inputs to the delay setting FFs 1 to 5 of the shift register 230 that have been supplied with delay setting data “1”, “0”, “0”, “0” and “0” as the current inputs. The value of the delay setting FF 2 is changed to “1” as the new input, which corresponds to a case where the delay setting data are shifted from the delay number 0 (delay No. 0) to the delay number 1 (delay No. 1) illustrated in FIG. 15A.

When the delay setting data are changed in this pattern, the current outputs of the selection signals 1 to 4 are “0”, “1”, “1” and “1”, respectively, the intermediate outputs of the selection signals 1 to 4 are “0”, “0”, “1” and “1”, respectively, and the new outputs of the selection signals 1 to 4 are “1”, “0”, “1” and “1”, respectively.

This illustrates the fact that since the selection signal 1 is “0” and the selection signal is “1” in the current outputs, the signal turning point is the selector 21, and the power-saving modes of the selectors 22, 23 and 24 situated away from the input terminal IN and the output terminal OUT of the fine delay adjustment circuit 110A are turned ON. Note that in this state, invalid data are present in an interval between the output terminal of the selector 24 and the output terminal of the inverter 32.

Further, since only the selection signal 2 is transitioned to “0” in the intermediate outputs, the power-saving mode of the selector 22 is turned OFF, and the input of the selector 22 is changed from the inverter 33 to the inverter 12. Hence, since the output of the inverter 12 is input into the selector 22, the invalid data present in the interval between the output terminal of the selector 22 and the output terminal of the inverter 32 are cleared.

That is, the operations by the intermediate outputs when the delay setting data are changed are similar to the operations of eliminating the invalid data by having the preparation period corresponding to one clock cycle when the signal turning point is switched from the selector 21 to the selector 22 in the first embodiment.

Note that in the intermediate outputs, the selection signal 2 being transitioned to “0” represents that the selection signal is reset.

In the new outputs, since only the selection signal 1 is changed to “1”, the input of the selector 21 is switched from the inverter 11 to the inverter 32. Hence, the selector 21 does not serve as the signal turning point, and the selector 22 serves as the signal turning point instead.

Note that when the signal turning point is switched from the selector 21 to selector 22, the selection signals 3 and 4 remain unchanged as “1”, and the selectors 23 and 24, and the inverters 33 and 34 are supplied with fixed data. However, the selectors 23 and 24 are not associated with the switching of the signal turning point. Hence, when the signal turning point is switched from the selector 21 to selector 22, the fixed data present in the selectors 23 and 24, and the inverters 33 and 34 will not be contained in the output signal of the delay adjustment circuit 110A.

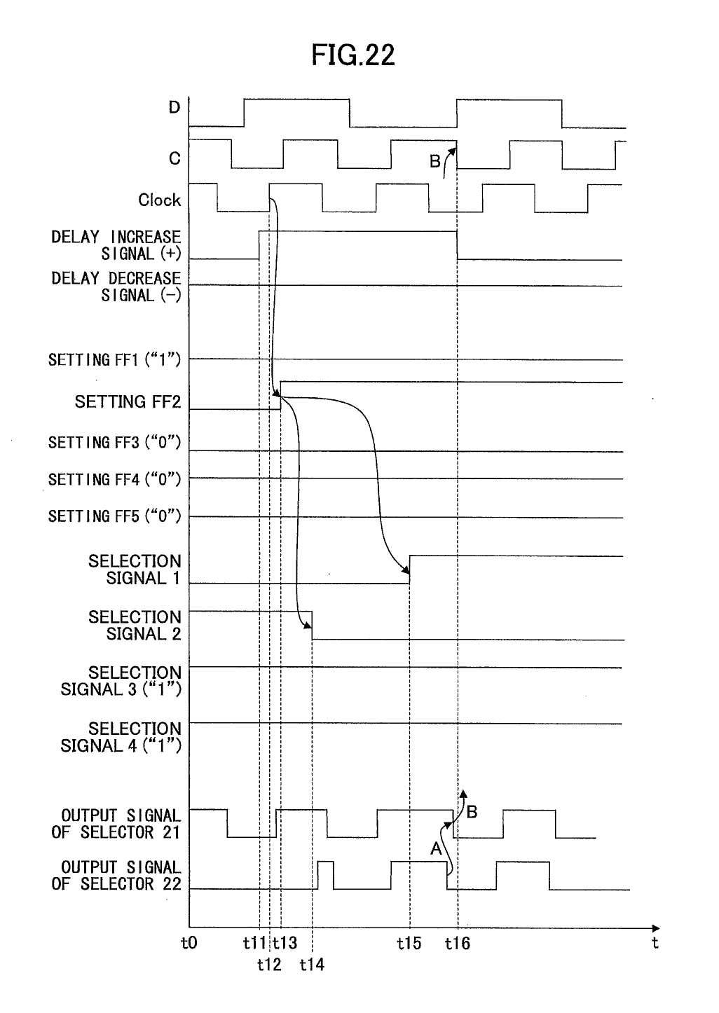

Next, a description will be given, with reference to a timing chart in FIG. 22, of operations of the signal delay device 200 of the second embodiment.

FIG. 22 is a diagram illustrating a timing chart indicating a relationship between the delay setting data and the selection signals in the delay adjustment circuit 110A for fine adjustment of the signal delay device 200 of the second embodiment.

In the following, a description is given of a case where the delay setting data illustrated in FIG. 15A are shifted from the delay number 0 (delay No. 0) to the delay number 1 (delay No. 1). That is, a description is given of a case where the signal turning point in the delay adjustment circuit 110B for coarse adjustment within the signal delay device 200 is fixed, and the signal turning point within the delay adjustment circuit 110A for fine adjustment is changed from the selector 21 to the selector 22.

As illustrated in FIG. 22, since the signal turning point of the signal delay device 200 is the selector 21, the selection signal 1 is “0”, and each of the selection signals 2 to 4 is “1”.

At time t11, when the phase difference between the data signal D and the capturing signal C being greater than a predetermined threshold is detected, the delay increase signal (+) rises to “1”. Note that the delay decrease signal (−) remains unchanged as “0”.

Note that the predetermined threshold may, for example, be set to the value representing the phase difference between the data signal D and the capturing signal C when the rise of the capturing signal C resides within a predetermined range before and after the center of the half cycle of the data signal D.

When the delay increase signal (+) rises to “1”, preparation for changing the signal turning point at the rise of the clock at time t12 is initiated, which allows the delay setting FF 2 to be “1” at time t13.

When the delay setting FF 2 is switched to “1”, the value of the selection signal 2 is switched to “0” of the intermediate output at time t14.

When the selection signal 2 is switched from “1” to “0”, data input from the input terminal IN of the delay adjustment circuit 110 are reflected in the inverter 32 via the inverter 12.

Hence, the invalid data present in an interval between the output terminal of the selector 22 and the output terminal of the inverter 32 are eliminated.

Next, the selection signal 1 is switched to “1” at time t15. The time interval between a time where the value of the delay setting FF2 is switched to “1” at time t13 and a time where the selection signal 1 is switched to “1” at time t15 corresponds to a delay time assigned by the buffer 252 in the transmission of the delay setting data of the delay setting FF 2.

At this moment, since the delay setting FF 3 remains unchanged as “0”, and the value of the selection signal 2 is “0”, the selector 22 serves as the signal turning point.

When the signal turning point is switched to the selector 22 at time t15, the output signal of the selector 22 is propagated to the selector 21 via the inverter 32. Hence, the fall of the output signal of the selector 22 is propagated as the fall of the output signal of the selector 21 as illustrated in an arrow A in FIG. 22.

Hence, the fall of the output signal of the selector 21 after time t15 is delayed.

Then, the delayed output signal of the selector 21 delays the capturing signal C output from the output terminal OUT of the delay adjustment circuit 110 as indicated by an arrow B.

Hence, the rise of the capturing signal C is thereafter situated at the center of the half cycle of the data signal D.

Note that at time t16, when the phase difference between the data signal D and the capturing signal C is less than or equal to the predetermined threshold, the delay increase signal (+) falls. That is, the phase difference between the data signal D and the capturing signal C is determined as being greater than the predetermined threshold in an interval between time 11 and time t16, where the delay increase signal (+) is at H level.

As described above, when the phase difference between the data signal D and the capturing signal C is greater than or equal to a predetermined threshold, the signal delay device 200 of the second embodiment initially eliminates the invalid data using the intermediate outputs of the selection signals, and changes the signal turning point after a delay time corresponding to one clock cycle time has elapsed.

Hence, the invalid data may be eliminated while awaiting the delay time, and the accurate data signal D may be captured without capturing the invalid data by capturing the data signal D using the delay adjusted capturing signal C.

Further, since the signal delay device 200 of the second embodiment may be able to capture the accurate data signal D as described above, the server 90 (see FIG. 9) including the signal delay device 200 of the second embodiment in the I/O port 99 may be able to suppress degraded operations due to capturing of the invalid data and exhibit improved operating stability and reliability.

According to the above-described embodiments, it may be possible to provide a signal delay device and a control method of the signal delay device capable of simply setting an amount of delay to be assigned to an input signal.

Although the embodiments are denoted as, for example, “first,” or “second”, these numbers do not specify priorities of the embodiments. Numerous other variations and modifications will be made, which is apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A signal delay device outputting a delay signal obtained by assigning a delay to an input signal, the signal delay device comprising:
a delay unit including a plurality of delay parts connected to one another in series and configured to generate the delay signal, the delay signal being obtained by causing at least one of the delay parts to assign the delay to the input signal;
a selection unit configured to output the delay signal, the selection unit including a plurality of selectors connected to one another in series, each of the selectors being configured to receive an output of a corresponding one of the delay parts, each of the selectors excluding a head one of the selectors being supplied with an output of a corresponding one of the former selectors, and outputting one of the output of the corresponding one of the delay parts and the output of the corresponding one of the former selectors, based on a selection signal supplied therein;
a register unit configured to hold delay setting data to set an amount of delay of the signal delay device; and
a selection signal generator configured to generate the selection signal indicating one of the selectors selecting an output of a corresponding one of the delay parts based on the delay setting data held by the register unit and output the generated selection signal to the selection unit.

2. The signal delay device as claimed in claim 1, wherein
each of the selectors outputs one of the output of a corresponding one of the delay parts and the output of a corresponding one of the former selectors based on a logical value of the selection signal supplied therein, and wherein
the register unit holds data having a plurality of digits being set as the delay setting data, and a logical value for outputting an output of one of the delay parts corresponding to one of the selectors is set to one of the digits of the delay setting data corresponding to the one of the selectors selecting the output of the corresponding one of the delay parts.

3. The signal delay device as claimed in claim 2, wherein
the delay setting data include data having specific consecutive logical values and a boundary of the specific consecutive logical values, the boundary corresponding to one of the digits corresponding to the one of the selectors selecting the output of the corresponding one of the delay parts.

4. The signal delay device as claimed in claim 2, further comprising:
a delay adjustment determining part configured to compare a phase of the delay signal output by the selector and a phase of a comparative signal, and output one of a delay increase signal to increase an amount of delay of the delay signal and a delay decrease signal to decrease an amount of delay of the delay signal based on a compared result, wherein
the register unit shifts the delay setting data based on one of the delay increase signal and the delay decrease signal.

5. The signal delay device as claimed in claim 4, further comprising:
an arithmetic circuit configured to output a signal indicating that the delay adjustment determining part has output one of the delay increase signal and the delay decrease signal, wherein
the selection signal generator inverts data corresponding to one of the digits of the delay setting data output by the register unit, the data corresponding to a selector selecting an output of a corresponding one of the delay parts based on the signal output by the arithmetic circuit, and outputs the inverted data into the selector as a selection signal.

6. The signal delay device as claimed in claim 4, further comprising:
an arithmetic circuit configured to output a signal indicating that the delay adjustment determining part has output one of the delay increase signal and the delay decrease signal, wherein
the selection signal generator includes a plurality of selection signal generating circuits corresponding to the selectors, each of the selection signal generating circuits having
a NAND circuit configured to output a NAND result of an inverted signal of an output signal from one of registers of the register unit and an output signal from an adjacent register adjacent to the one of registers in a direction in which the amount of delay of the delay signal is decreased, and
a selection circuit configured to select an output of the NAND circuit supplied with an inverted signal of an output signal of the one of the registers and an output of the one of the registers as a selection signal based on a value of the output of the arithmetic circuit.

7. The signal delay device as claimed in claim 4, wherein
the selection signal generator includes a delay circuit configured to assign a delay to an output signal from a register forming the register unit, and
a NAND circuit corresponding to any one of the selectors, the NAND circuit being configured to output a NAND result of an inverted signal of an output of the delay circuit and an output signal from an adjacent register adjacent to one of the registers in a direction in which an amount of delay of the delay signal is decreased, the one of the registers being configured to assign a delay to an output signal of the one of the registers.

8. The signal delay device as claimed in claim 1, wherein
each of the delay parts is formed of an inverter circuit, and
each of the selectors is formed of a selector circuit and an inverter circuit.

9. A control method for a signal delay device, the signal delay device including a register unit configured to hold delay setting data based on an amount of delay assigned to an input signal, a delay unit including a plurality of delay parts connected to one another in series and configured to assign a delay to the input signal, and a selection unit including a plurality of selectors connected to one another in series, each of the selectors being configured to receive an output of a corresponding one of the delay parts, each of the selectors excluding a head one of the selectors being supplied with an output of a corresponding one of the former selectors, and outputting one of the output of the corresponding one of the delay parts and the output of the corresponding one of the former selectors,
the control method comprising:
outputting a selection signal indicating one of the selectors selecting an output of a corresponding one of the delay parts based on the delay setting data held by the register unit; and
selecting an output signal from the delay parts by the selector indicated by the output selection signal and outputting a delay signal from the selection unit.
